(19) United States
(12) Patent Application Publication
(10) Pub. No.: US 2026/0156814 A1
(43) Pub. Date: Jun. 4, 2026

(54) SEMICONDUCTOR DEVICES INCLUDING VERTICAL ACTIVE PATTERNS

(71) Applicant: SAMSUNG ELECTRONICS CO., LTD., Suwon-si (KR)

(72) Inventors: Taehyuk Kim, Suwon-si (KR); Suklae Kim, Suwon-si (KR); Taekyong Kim, Suwon-si (KR); Taejin Park, Suwon-si (KR)

(73) Assignee: SAMSUNG ELECTRONICS CO., LTD., Suwon-si (KR)

(21) Appl. No.: 19/407,523

(22) Filed: Dec. 3, 2025

(30) Foreign Application Priority Data
Dec. 4, 2024 (KR) 10-2024-0178429

(51) Int. Cl. H10B 12/00; H01L 23/00; H10D 1/68; H10D 30/63

(52) U.S. Cl. CPC H10B 12/50; H10B 12/315; H10B 12/482; H10D 1/716; H10D 30/63; H10B 12/033; H10B 12/05; H10B 12/09; H10W 90/792

(57) ABSTRACT

A semiconductor device may include a memory region and a peripheral region. The memory region may include cell vertical active patterns, cell gate electrodes, cell upper source/drain patterns, cell contact plugs, a cell separation pattern, and a data storage structure on the cell contact plugs and the cell separation pattern. The peripheral region may include peripheral vertical active patterns, peripheral gate electrodes having side surfaces facing side surfaces of the peripheral vertical active patterns, and peripheral upper source/drain patterns and peripheral upper interconnections on the peripheral vertical active patterns. Each of the cell upper source/drain patterns may contact a corresponding one of the cell vertical active patterns. The peripheral upper source/drain patterns may include a first peripheral upper source/drain pattern, and the first peripheral upper source/drain pattern may contact first and second peripheral vertical active patterns among the peripheral vertical active patterns.

### CROSS-REFERENCE TO RELATED APPLICATION

This application claims the benefit under 35 USC 119(a) of Korean Patent Application No. 10-2024-0178429 filed on Dec. 4, 2024, in the Korean Intellectual Property Office, the entire disclosure of which is incorporated herein by reference for all purposes.

### BACKGROUND

Some embodiments of the present disclosure relate to semiconductor devices including vertical active patterns.

As the demand for high performance, high speed, and/or multi-functionality of semiconductor devices increases, the integration of semiconductor devices is increasing. In manufacturing semiconductor devices with fine patterns corresponding to the trend toward high integration of semiconductor devices, implementation of patterns having fine widths or fine spacings is required.

### SUMMARY

According to some example embodiments of the present disclosure, a semiconductor device may be provided and include a peripheral transistor having a vertical active pattern disposed in a peripheral region.

According to some example embodiments of the present disclosure, a semiconductor device may be provided and include: a memory region; and a peripheral region, wherein the memory region includes: cell vertical active patterns; cell gate electrodes, wherein side surfaces of the cell gate electrodes face side surfaces of the cell vertical active patterns; cell upper source/drain patterns on the cell vertical active patterns; at least one cell contact plug on the cell upper source/drain patterns; a cell separation pattern on a side surface of the cell upper source/drain patterns and a side surface of the at least one cell contact plug; and a data storage structure on the at least one cell contact plug and the cell separation pattern, wherein the peripheral region includes: peripheral vertical active patterns; peripheral gate electrodes, wherein side surfaces of the peripheral gate electrodes face side surfaces of the peripheral vertical active patterns; peripheral upper source/drain patterns on the peripheral vertical active patterns; at least one peripheral upper interconnection on the peripheral upper source/drain patterns, wherein each of the cell upper source/drain patterns contacts a corresponding one of the cell vertical active patterns, wherein the peripheral upper source/drain patterns include a first peripheral upper source/drain pattern, and wherein the first peripheral upper source/drain pattern contacts a first peripheral vertical active pattern and a second peripheral vertical active pattern among the peripheral vertical active patterns.

According to some example embodiments of the present disclosure, a semiconductor device may be provided and include: a memory region; and a peripheral region, wherein the memory region includes: cell vertical active patterns; cell gate electrodes, wherein side surfaces of the cell gate electrodes face side surfaces of the cell vertical active patterns; cell upper source/drain patterns on the cell vertical active patterns; at least one cell contact plug on the cell upper source/drain patterns; a cell separation pattern on a side surface of the cell upper source/drain patterns and a side surface of the at least one cell contact plug; and a data storage structure on the at least one cell contact plug and the cell separation pattern, wherein the peripheral region includes: peripheral vertical active patterns; peripheral gate electrodes, wherein side surfaces of the peripheral gate electrodes face side surfaces of the peripheral vertical active patterns; peripheral upper source/drain patterns on the peripheral vertical active patterns; at least one peripheral upper interconnection on the peripheral upper source/drain patterns, wherein the cell upper source/drain patterns respectively contact a corresponding one of the cell vertical active patterns, and wherein a horizontal width of each of the peripheral upper source/drain patterns is greater than a horizontal width of each of the cell upper source/drain patterns.

According to some example embodiments of the present disclosure, a semiconductor device may be provided and include: a memory region; and a peripheral region, wherein the memory region includes: cell vertical active patterns; cell gate electrodes, wherein side surfaces of the cell gate electrodes face side surfaces of the cell vertical active patterns; contact structures on the cell vertical active patterns; a cell separation pattern on side surfaces of the contact structures; a data storage structure on the contact structures and the cell separation pattern; an insulating layer on the data storage structure and extending onto the peripheral region; and an upper contact plug penetrating through the insulating layer and connected to the data storage structure, wherein the peripheral region includes: peripheral vertical active patterns; peripheral gate electrodes, wherein side surfaces of the peripheral gate electrodes face side surfaces of the peripheral vertical active patterns; peripheral interconnection structures on the peripheral vertical active patterns; and peripheral upper contact plugs penetrating the insulating layer and connected to the peripheral interconnection structures, and wherein the peripheral interconnection structures respectively contact a plurality of peripheral vertical active patterns among the peripheral vertical active patterns, and the peripheral interconnection structures are lower than a lower surface of the data storage structure.

According to some example embodiments of the present disclosure, a method of manufacturing a semiconductor device may be provided and include: forming cell vertical active patterns and peripheral vertical active patterns; forming cell gate electrodes and peripheral gate electrodes, wherein surfaces of the cell gate electrodes face side surfaces of the cell vertical active patterns, and side surfaces of the peripheral gate electrodes face side surfaces of the peripheral vertical active patterns; forming cell upper source/drain patterns and peripheral upper source/drain patterns, wherein the cell upper source/drain patterns are on the cell upper source/drain patterns, and the peripheral upper source/drain patterns are on the peripheral vertical active patterns; forming at least one cell contact plug on the cell upper source/drain patterns; forming a cell separation pattern on a side surface of the cell upper source/drain patterns and a side surface of the at least one cell contact plug; forming a data storage structure on the at least one cell contact plug and the cell separation pattern; and forming at least one peripheral upper interconnection on the peripheral upper source/drain patterns, wherein each of the cell upper source/drain patterns contacts a corresponding one of the cell vertical active patterns, wherein the peripheral upper source/drain patterns include a first peripheral upper source/drain pattern, and wherein the first peripheral upper source/drain pattern contacts a first peripheral vertical active pattern and a second peripheral vertical active pattern among the peripheral vertical active patterns.

According to some example embodiments of the present disclosure, the peripheral upper source/drain patterns are at a same level as a level of the cell upper source/drain patterns.

According to some example embodiments of the present disclosure, the at least one peripheral upper interconnection is at a same level as a level of the at least one cell contact plug.

According to some example embodiments of the present disclosure, the peripheral vertical active patterns are at a same level as a level of the cell vertical active patterns.

### BRIEF DESCRIPTION OF DRAWINGS

The and other aspects, features, and advantages of embodiments of the present disclosure will be more clearly understood from the following detailed description, taken in conjunction with the accompanying drawings, in which:

FIG. 1 is a conceptual perspective view of a semiconductor device according to an example embodiment;

FIG. 2 is a circuit diagram illustrating a memory region of a semiconductor device according to an example embodiment;

FIG. 3 is a plan view of a semiconductor device according to an example embodiment;

FIG. 4 is a vertical cross-sectional view taken along a line I-I′ of the semiconductor device illustrated in FIG. 3;

FIGS. 5A and 5B are enlarged views of portions of the semiconductor device illustrated in FIG. 4;

FIG. 6 is a conceptual perspective view illustrating a bit line shield structure according to an example embodiment;

FIGS. 7 to 11 are vertical cross-sectional views of a semiconductor device according to an example embodiment;

FIGS. 12 to 27 are vertical cross-sectional views illustrated according to a process sequence to describe a method of manufacturing a semiconductor device according to an example embodiment.

### DETAILED DESCRIPTION

Hereinafter, terms such as “upper,” “middle,” “intermediate,” “lower,” and the like may be replaced with other terms, such as “first,” “second,” “third,” and the like to describe components of the specification. Although terms such as “first,” “second,” and “third” may be used to describe various components, the components are not limited by the terms, and a “first component” may be referred to as a “second component.” In the specification, terms such as “lower,” “upper,” “top,” and “bottom” may be terms described based on the drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

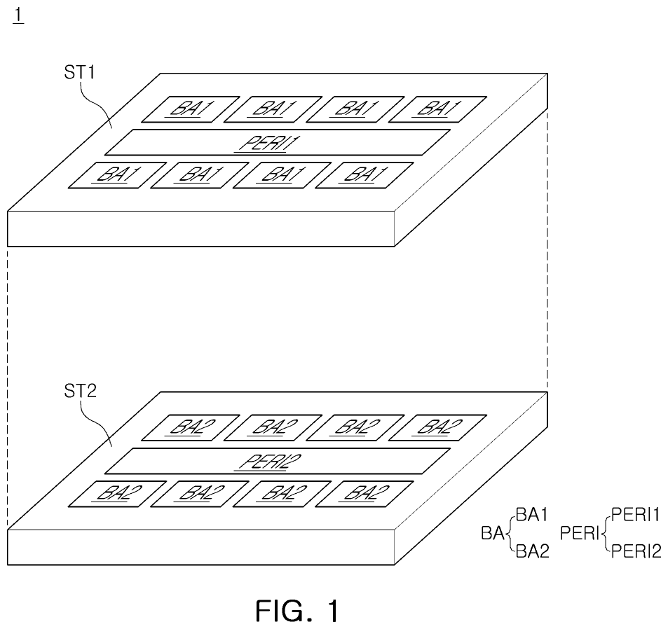

With reference to FIG. 1, a semiconductor device according to an example embodiment is described below. FIG. 1 is a conceptual perspective view illustrating a semiconductor device according to an example embodiment.

Referring to FIG. 1, a semiconductor device 1 according to an example embodiment may include a first structure ST1 and a second structure ST2 vertically overlapping with the first structure ST1. The second structure ST2 may be disposed below the first structure ST1.

In an example embodiment, the first structure ST1 may be a first chip structure including a memory region and a peripheral region, and the second structure ST2 may be a second chip structure including a second peripheral circuit. The first structure ST1 and the second structure ST2 may be formed by being bonded by a bonding process such as a wafer bonding process. Therefore, the first structure ST1 may be in contact with and bonded to the second structure ST2.

The semiconductor device 1 may include a plurality of banks BA and an outer peripheral region PERI.

The outer peripheral region PERI may include a first peripheral region PERI1 within the first structure ST1 and a second peripheral region PERI2 within the second structure ST2. The outer peripheral region PERI may be a peripheral region in which peripheral circuits for input/output of data or commands, or input of power/ground, are disposed.

Each of the plurality of banks BA may include a first bank region BA1 within the first structure ST1, and a second bank region BA2 within the second structure ST2.

The first bank region BA1 within the first structure ST1 may include memory cells. The second bank region BA2 within the second structure ST2 may include peripheral circuits such as a sense amplifier and a sub word line driver.

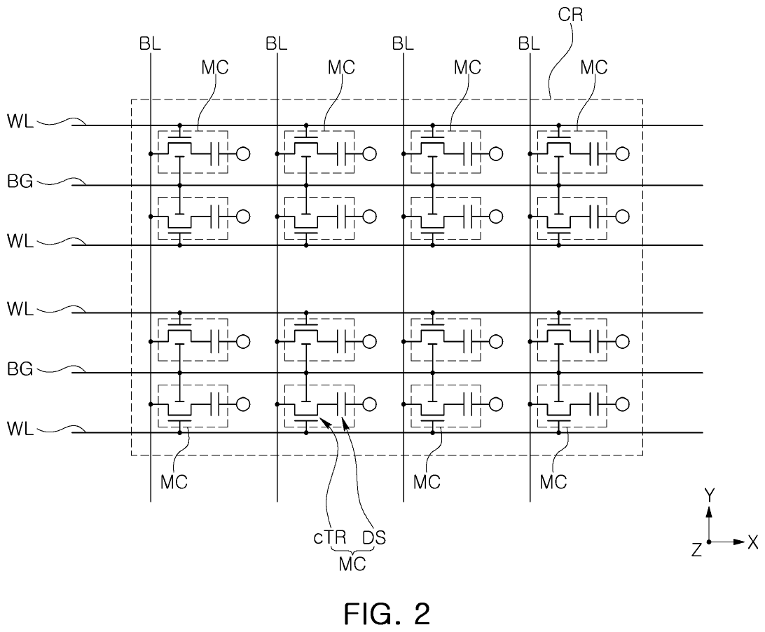

Next, referring to FIG. 2, the circuit of the memory region of the first structure ST1 will be described. FIG. 2 is a circuit diagram illustrating a memory region of a semiconductor device according to an example embodiment.

Referring to FIG. 2, the memory region CR may include memory cells MC. The memory region CR may include memory cells MC arranged in the first direction X and the second direction Y, word lines WL connected to the memory cells MC and extending in the first direction X, and bit lines BL connected to the memory cells MC and extending in the second direction Y. The first direction X and the second direction Y may be perpendicular to each other.

The word lines WL may cross the memory region CR in the first direction X. The bit lines BL may cross the memory region CR in the second direction Y.

Each of the memory cells MC may include a data storage structure DS that may serve as data storage, and a cell transistor cTR electrically connected to the data storage structure DS. In a memory such as dynamic random access memory (DRAM), the data storage structure DS may be a cell capacitor that may store data.

The memory region CR may further include back gate lines BG. The respective back gate lines BG may be disposed between a pair of word lines WL that are adjacent to each other in the second direction Y among the word lines WL. The respective back gate lines BG may be disposed between vertical channel regions of the cell transistors cTR.

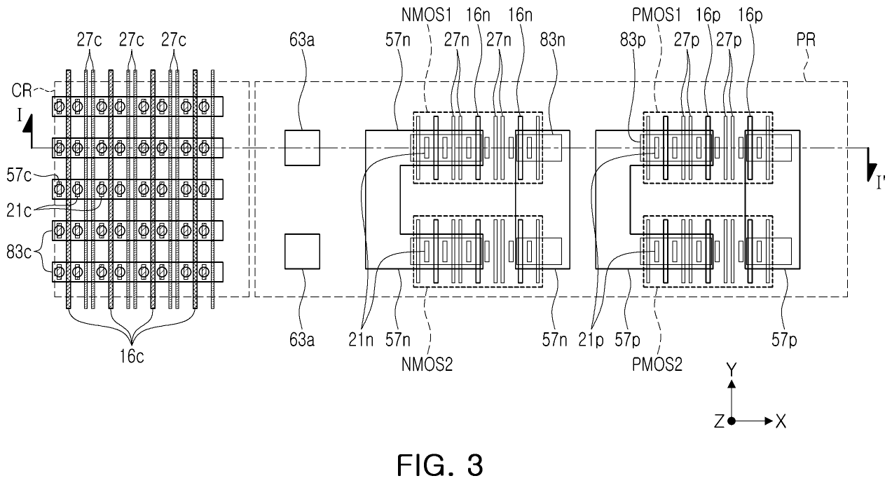

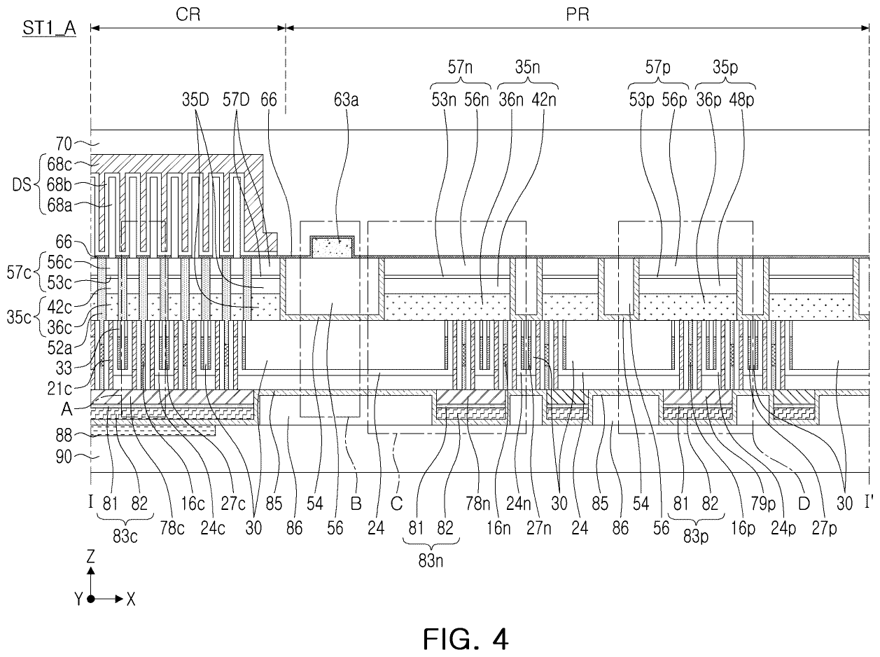

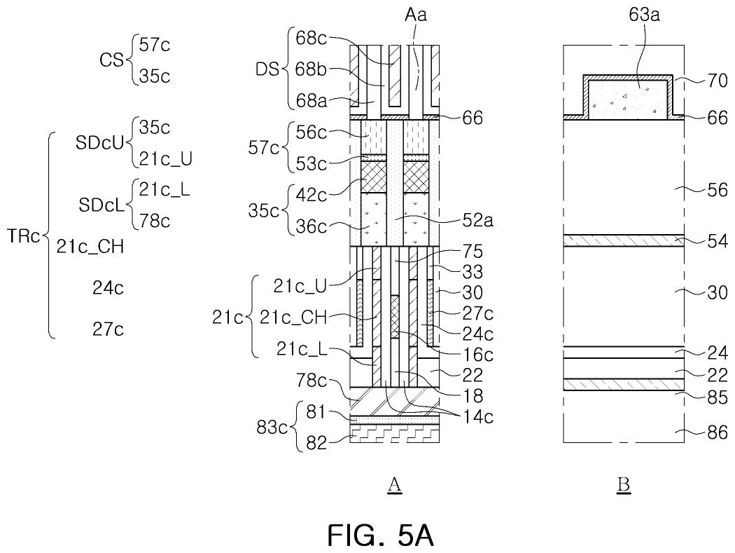

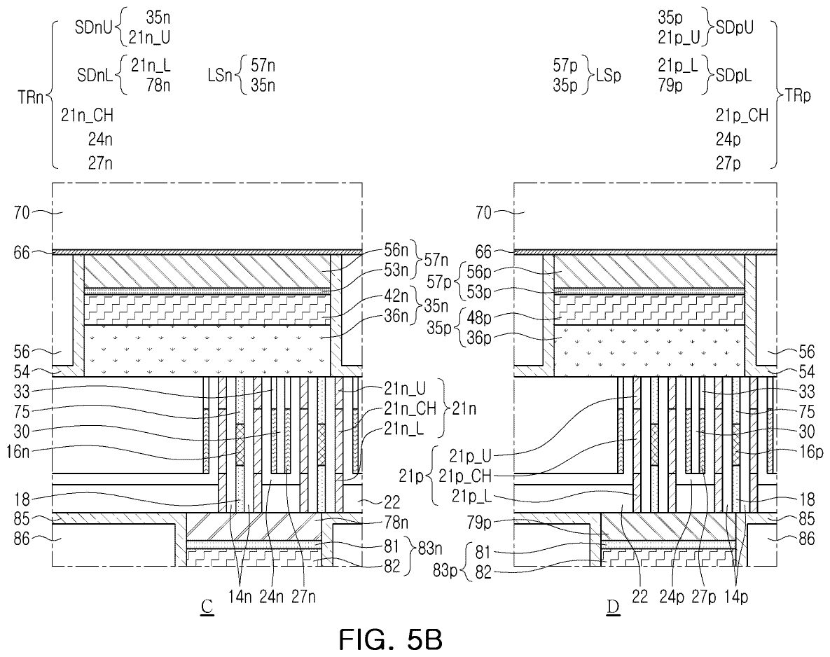

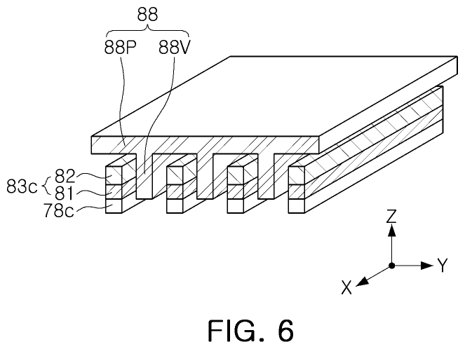

Hereinafter, with reference to FIGS. 3 to 6, together with FIGS. 1 and 2, an illustrative example of a first portion ST1_A of the first structure ST1 of a semiconductor device according to an example embodiment will be described. FIG. 3 is a plan view of a semiconductor device according to an example embodiment. FIG. 4 is a vertical cross-sectional view along a line I-I′ of the semiconductor device illustrated in FIG. 3. FIGS. 5A and 5B are enlarged views of portions of the semiconductor device illustrated in FIG. 4. FIG. 6 is a conceptual perspective view illustrating a bit line shield structure according to an example embodiment.

Referring to FIGS. 1, 2, 3, 4, 5A, 5B, and 6, the first structure ST1 of the semiconductor device 1 may include a memory region CR and a peripheral region PR. Hereinafter, the memory region CR and the peripheral region PR within the first portion ST1_A of the first structure ST1 of the semiconductor device 1 will be described.

The memory region CR may include cell vertical active patterns 21c, cell gate electrodes 27c, cell upper source/drain patterns 35c, cell contact plugs 57c, and cell separation patterns 52a. The peripheral region PR may include first peripheral vertical active patterns 21n, first peripheral gate electrodes 27n, first peripheral upper source/drain patterns 35n, and first peripheral upper interconnections 57n. The peripheral region PR may further include second peripheral vertical active patterns 21p, second peripheral gate electrodes 27p, second peripheral upper source/drain patterns 35p, and second peripheral upper interconnections 57p.

Each of the cell vertical active patterns 21c may include a cell lower source/drain region 21c_L, a cell vertical channel region 21c_CH on the cell lower source/drain region 21c_L, and a cell upper source/drain region 21c_U on the cell vertical channel region 21c_CH. Each of the first peripheral vertical active patterns 21n may include a first peripheral lower source/drain region 21n_L, a first peripheral vertical channel region 21n_CH on the first peripheral lower source/drain region 21n_L, and a first peripheral upper source/drain region 21n_U on the first peripheral vertical channel region 21n_CH. Each of the second peripheral vertical active patterns 21p may include a second peripheral lower source/drain region 21p_L, a second peripheral vertical channel region 21p_CH on the second peripheral lower source/drain region 21p_L, and a second peripheral upper source/drain region 21p_U on the second peripheral vertical channel region 21p_CH.

The cell gate electrodes 27c may be the word lines WL described in FIG. 2. The cell gate electrodes 27c may have side surfaces facing side surfaces of the cell vertical active patterns 21c. The first peripheral gate electrodes 27n may have side surfaces facing side surfaces of the first peripheral vertical active patterns 21n. The second peripheral gate electrodes 27p may have side surfaces facing side surfaces of the second peripheral vertical active patterns 21p.

Each of the cell upper source/drain patterns 35c may include a first cell upper source/drain pattern 36c and a second cell upper source/drain pattern 42c that are sequentially stacked. The side surfaces of the first cell upper source/drain pattern 36c and the second cell upper source/drain pattern 42c may be aligned and coplanar with each other. Each of the first peripheral upper source/drain patterns 35n may include a first peripheral upper source/drain layer 36n and a second peripheral upper source/drain layer 42n that are sequentially stacked. Side surfaces of the first peripheral upper source/drain layer 36n and the second peripheral upper source/drain layer 42n may be aligned and coplanar with each other. Each of the second peripheral upper source/drain patterns 35p may include a third peripheral upper source/drain layer 36p and a fourth peripheral upper source/drain layer 48p that are sequentially stacked. Side surfaces of the third peripheral upper source/drain layer 36p and the fourth peripheral upper source/drain layer 48p may be aligned and coplanar with each other.

The cell upper source/drain patterns 35c may have an N-type conductivity type. The first peripheral upper source/drain patterns 35n may have an N-type conductivity type. The second peripheral upper source/drain patterns 35p may have a P-type conductivity type.

The second cell upper source/drain pattern 42c may have an impurity concentration higher than an impurity concentration of the first cell upper source/drain pattern 36c. An impurity concentration of the first cell upper source/drain pattern 36c may be higher than an impurity concentration of the first cell upper source/drain region 21c_U. The second peripheral upper source/drain layer 42n may have an impurity concentration higher than an impurity concentration of the first peripheral upper source/drain layer 36n. An impurity concentration of the first peripheral upper source/drain layer 36n may be higher than the impurity concentration of the first peripheral upper source/drain region 21n_U. The fourth peripheral upper source/drain layer 48p may have an impurity concentration higher than an impurity concentration of the third peripheral upper source/drain layer 36p. An impurity concentration of the third peripheral upper source/drain layer 36p may be higher than an impurity concentration of the third peripheral upper source/drain region 21p_U.

The upper source/drain patterns (e.g., the cell upper source/drain patterns 35c, the first peripheral upper source/drain patterns 35n, and the second peripheral upper source/drain patterns 35p) may vertically overlap with the vertical active patterns (e.g., the cell vertical active patterns 21c, the first peripheral vertical active patterns 21n, and the second peripheral vertical active patterns 21p) and may be in contact with the vertical active patterns (e.g., the cell vertical active patterns 21c, the first peripheral vertical active patterns 21n, and the second peripheral vertical active patterns 21p). The width of each of the upper source/drain patterns (e.g., the cell upper source/drain patterns 35c, the first peripheral upper source/drain patterns 35n, and the second peripheral upper source/drain patterns 35p) in the first horizontal direction X may be greater than the width of each of the vertical active patterns (e.g., the cell vertical active patterns 21c, the first peripheral vertical active patterns 21n, and the second peripheral vertical active patterns 21p) in the first horizontal direction X. The memory region CR and the peripheral region PR may further include dummy source/drain patterns 35D that are disposed at the same level as the upper source/drain patterns (e.g., the cell upper source/drain patterns 35c, the first peripheral upper source/drain patterns 35n, and the second peripheral upper source/drain patterns 35p) and formed of the same material and structure as the upper source/drain patterns (e.g., the cell upper source/drain patterns 35c, the first peripheral upper source/drain patterns 35n, and the second peripheral upper source/drain patterns 35p). The dummy source/drain patterns 35D may be spaced apart from the vertical active patterns (e.g., the cell vertical active patterns 21c, the first peripheral vertical active patterns 21n, and the second peripheral vertical active patterns 21p).

The cell contact plugs 57c may be disposed on the cell upper source/drain patterns 35c. Each of the cell contact plugs 57c may include a metal-semiconductor compound layer 53c that contacts the upper surface of the second cell upper source/drain pattern 42c, and a plug pattern 56c on the metal-semiconductor compound layer 53c. The cell upper source/drain patterns 35c and the cell contact plugs 57c that are sequentially stacked may have side surfaces that are aligned with each other and may form a coplanar surface. The cell upper source/drain patterns 35c and the cell contact plugs 57c may form contact structures CS. The side surfaces of the contact structures CS may be defined by the cell separation pattern 52a.

The first peripheral upper interconnections 57n may be disposed on the first peripheral upper source/drain patterns 35n. Each of the first peripheral upper interconnections 57n may include a metal-semiconductor compound layer 53n that contacts an upper surface of the second peripheral upper source/drain layer 42n, and a conductive layer 56n on the metal-semiconductor compound layer 53n. The first peripheral upper source/drain patterns 35n and the first peripheral upper interconnections 57n, which are sequentially stacked, may have side surfaces that are aligned with each other. The side surfaces of the first peripheral upper interconnections 57n may be aligned with the side surfaces of the first peripheral upper source/drain patterns 35n and may form a coplanar surface. The metal-semiconductor compound layer 53n and the conductive layer 56n may include the same material as the metal-semiconductor compound layer 53c and the plug pattern 56c, respectively, and may be disposed at the same level as the metal-semiconductor compound layer 53c and the plug pattern 56c. The first peripheral upper source/drain patterns 35n and the first peripheral upper interconnections 57n may form first peripheral interconnection structures LSn. The second peripheral upper source/drain patterns 35p and the second peripheral upper interconnections 57p may form second peripheral interconnection structures LSp. The contact structures CS, the first peripheral interconnection structures LSn, and the second peripheral interconnection structures LSp may be disposed at the same level as each other.

As illustrated in FIGS. 3 and 4, the horizontal width of the first peripheral upper interconnections 57n may be larger than the horizontal width of the cell contact plugs 57c. In addition, the horizontal width of the first peripheral upper source/drain patterns 35n may be larger than the horizontal width of the cell contact plugs 57c.

The second peripheral upper interconnections 57p may be disposed on the second peripheral upper source/drain patterns 35p. Each of the second peripheral upper interconnections 57p may include a metal-semiconductor compound layer 53p in contact with the upper surface of the fourth peripheral upper source/drain layer 48p, and a conductive layer 56p on the metal-semiconductor compound layer 53p. The second peripheral upper source/drain patterns 35p and the second peripheral upper interconnections 57p that are sequentially stacked may have side surfaces that are aligned with each other. The side surfaces of the second peripheral upper interconnections 57p may be aligned with the side surfaces of the second peripheral upper source/drain patterns 35p and may form a coplanar surface. The metal-semiconductor compound layer 53p and the conductive layer 56p may include the same material as the metal-semiconductor compound layer 53c and the plug pattern 56c, respectively, and may be disposed at the same level as the metal-semiconductor compound layer 53c and the plug pattern 56c.

As illustrated in FIGS. 3 and 4, the horizontal width of the second peripheral upper interconnections 57p may be larger than the horizontal width of the cell contact plugs 57c. In addition, the horizontal width of the second peripheral upper source/drain patterns 35p may be larger than the horizontal width of the cell contact plugs 57c.

The cell contact plugs 57c, the first peripheral upper interconnections 57n, and the second peripheral upper interconnections 57p may be aligned with and in contact with the upper source/drain patterns (e.g., the cell upper source/drain patterns 35c, the first peripheral upper source/drain patterns 35n, and the second peripheral upper source/drain patterns 35p). The memory region CR and the peripheral region PR may further include dummy contact plugs 57D aligned with and in contact with the dummy source/drain patterns 35D. The dummy contact plugs 57D may be disposed at the same level as the cell contact plugs 57c, the first peripheral upper interconnections 57n, and the second peripheral upper interconnections 57p, and may be formed of the same material and the same structure as the cell contact plugs 57c, the first peripheral upper interconnections 57n, and the second peripheral upper interconnections 57p.

The cell separation pattern 52a may define side surfaces of the cell upper source/drain patterns 35c and the cell contact plugs 57c that are sequentially stacked. The cell separation pattern 52a may surround side surfaces of the cell upper source/drain patterns 35c and the cell contact plugs 57c that are sequentially stacked. The cell separation pattern 52a may include an insulating material.

The peripheral region PR may further include a pad pattern 63a. The memory region CR and the peripheral region PR may further include an insulating liner 66.

The pad pattern 63a may not vertically overlap with the first peripheral upper interconnections 57n and the second peripheral upper interconnections 57p. The insulating liner 66 may be disposed on the cell contact plugs 57c, the cell separation pattern 52a, and the pad pattern 63a. The insulating liner 66 may cover upper surfaces of the cell contact plugs 57c and the cell separation pattern 52a in the memory region CR, and may cover upper surfaces and side surfaces of the pad pattern 63a in the peripheral region PR. The insulating liner 66 may include an insulating material such as SiN, SiBN, SiCN, or a high-κ dielectric.

The insulating liner 66 includes a first portion disposed on the upper surface of the cell separation pattern 52a, and a second portion disposed on the upper surface of the pad pattern 63a, and the second portion of the insulating liner 66 may be disposed at a higher level than a level of the first portion of the insulating liner 66.

The memory region CR and the peripheral region PR may further include a data storage structure DS and an insulating layer 70.

The data storage structure DS may include first electrodes 68a connected to the cell contact plugs 57c (e.g., cell plug patterns)within the memory region CR, penetrating the insulating liner 66 and extending in the vertical direction Z, a second electrode 68c on side surfaces and upper surfaces of the first electrodes 68a, and a dielectric layer 68b between the first electrodes 68a and the second electrode 68c. The data storage structure DS may be a cell capacitor of a memory such as a DRAM.

The insulating layer 70 may cover the data storage structure DS within the memory region CR and the insulating liner 66 within the peripheral region PR. The insulating layer 70 may include at least one from among silicon oxide and a low-κ dielectric.

The memory region CR and the peripheral region PR may further include lower source/drain patterns (e.g., a cell lower source/drain pattern 78c, a first peripheral lower source/drain pattern 78n, and a second peripheral lower source/drain pattern 79p) connected to the vertical active patterns (e.g., the cell vertical active patterns 21c, the first peripheral vertical active patterns 21n, and the second peripheral vertical active patterns 21p) below the vertical active patterns (e.g., the cell vertical active patterns 21c, the first peripheral vertical active patterns 21n, and the second peripheral vertical active patterns 21p) and conductive patterns (e.g., a bit line 83c, a first peripheral lower interconnection 83n, and a second peripheral lower interconnection 83p) aligned with the lower source/drain patterns (e.g., the cell lower source/drain pattern 78c, the first peripheral lower source/drain pattern 78n, and the second peripheral lower source/drain pattern 79p) below the lower source/drain patterns (e.g., the cell lower source/drain pattern 78c, the first peripheral lower source/drain pattern 78n, and the second peripheral lower source/drain pattern 79p).

The lower source/drain patterns may include a cell lower source/drain pattern 78c connected to the cell vertical active patterns 21c, a first peripheral lower source/drain pattern 78n connected to the first peripheral vertical active patterns 21n, and a second peripheral lower source/drain pattern 79p connected to the second peripheral vertical active patterns 21p.

The conductive patterns may include a bit line 83c that is in contact with and aligned with the cell lower source/drain pattern 78c, a first peripheral lower interconnection 83n that is in contact with and aligned with the first peripheral lower source/drain pattern 78n, and a second peripheral lower interconnection 83p that is in contact with and aligned with the second peripheral lower source/drain pattern 79p. Each of the conductive patterns (e.g., the bit line 83c, the first peripheral lower interconnection 83n, and the second peripheral lower interconnection 83p) may include a first conductive layer 81 and a second conductive layer 82 disposed below the first conductive layer 81. The bit line 83c may be the bit line BL described in FIG. 2. The conductive patterns (e.g., the bit line 83c, the first peripheral lower interconnection 83n, and the second peripheral lower interconnection 83p) may include the same material as each other and may be disposed at the same level as each other.

The memory region CR may further include cell gate dielectric layers 24c, cell back gate electrodes 16c, cell back gate dielectric layers 14c, and insulating layers (e.g., back gate capping insulating layers 18, insulating layers 22, gate capping insulating layers 33, separation insulating layers 30, and insulating layers 75). The peripheral region PR may further include first peripheral gate dielectric layers 24n, first peripheral back gate electrodes 16n, first peripheral back gate dielectric layers 14n, second peripheral gate dielectric layers 24p, second peripheral back gate electrodes 16p, second peripheral back gate dielectric layers 14p, insulating layers (e.g., the back gate capping insulating layers 18, the insulating layers 22, the gate capping insulating layers 33, the separation insulating layers 30, and the insulating layers 75), and insulating structures (e.g., an insulating liner 54 and insulating pattern 56).

The cell back gate electrodes 16c may be the back gate lines BG described with reference to FIG. 2. The cell gate electrodes 27c may respectively extend in the second horizontal direction Y. The cell gate electrodes 27c may be spaced apart from each other in the first horizontal direction X perpendicular to the second horizontal direction Y. Each of the cell back gate electrodes 16c may have a line shape extending in the second horizontal direction Y.

Among the cell back gate electrodes 16c, a pair of cell back gate electrodes 16c adjacent to each other in the first horizontal direction X may be disposed between the cell gate electrodes 27c. In a plane, each of the cell vertical active patterns 21c may have a bar shape extending in the second horizontal direction Y. Each of the cell vertical active patterns 21c may be disposed between a cell back gate electrode 16c and a cell gate electrode 27c adjacent to each other among the cell back gate electrodes 16c and the cell gate electrodes 27c.

Each of the first peripheral gate electrodes 27n may extend in the second horizontal direction Y. Each of the first peripheral back gate electrodes 16n may have a line shape extending in the second horizontal direction Y. Among the first peripheral gate electrodes 27n, a pair of first peripheral gate electrodes 27n adjacent to each other in the first horizontal direction X may be disposed between a pair of first peripheral back gate electrodes 16n adjacent to each other in the first horizontal direction X. In a plane, each of the first peripheral vertical active patterns 21n may have a bar shape extending in the second horizontal direction Y. Each of the first peripheral vertical active patterns 21n may be disposed between a first peripheral back gate electrode 16n and a first peripheral gate electrode 27n adjacent to each other among the first peripheral back gate electrodes 16n and the first peripheral gate electrodes 27n.

Each of the second peripheral gate electrodes 27p may extend in the second horizontal direction Y. Each of the second peripheral back gate electrodes 16p may have a line shape extending in the second horizontal direction Y. Among the second peripheral gate electrodes 27p, a pair of second peripheral gate electrodes 27p adjacent to each other in the first horizontal direction X may be disposed between a pair of the second peripheral back gate electrodes 16p adjacent to each other in the first horizontal direction X. In a plane, each of the second peripheral vertical active patterns 21p may have a bar shape extending in the second horizontal direction Y. Each of the second peripheral vertical active patterns 21p may be disposed between the second peripheral back gate electrodes 16p and the second peripheral gate electrodes 27p that are adjacent to each other among the second peripheral back gate electrodes 16p and the second peripheral gate electrodes 27p.

The cell gate dielectric layers 24c may be disposed between the side surfaces of the cell vertical active patterns 21c and the cell gate electrodes 27c. The cell gate dielectric layers 24c may extend to cover the lower surfaces of the cell vertical active patterns 21c. The first peripheral gate dielectric layers 24n may be disposed between the side surfaces of the first peripheral vertical active patterns 21n and the first peripheral gate electrodes 27n. The first peripheral gate dielectric layers 24n may extend to cover the lower surfaces of the first peripheral vertical active patterns 21n. The second peripheral gate dielectric layers 24p may be disposed between the side surfaces of the second peripheral vertical active patterns 21p and the second peripheral gate electrodes 27p. The second peripheral gate dielectric layers 24p may extend to cover the lower surfaces of the second peripheral vertical active patterns 21p.

The cell back gate dielectric layers 14c may be disposed between the cell vertical active patterns 21c and the cell back gate electrodes 16c. The first peripheral back gate dielectric layers 14n may be disposed between the first peripheral vertical active patterns 21n and the first peripheral back gate electrodes 16n. The second peripheral back gate dielectric layers 14p may be disposed between the second peripheral vertical active patterns 21p and the second peripheral back gate electrodes 16p.

The back gate capping insulating layers 18 may be disposed below the lower surfaces of the back gate electrodes (e.g., the cell back gate electrodes 16c, the first peripheral back gate electrodes 16n, and the second peripheral back gate electrodes 16p). The insulating layers 75 may be disposed on the upper surfaces of the back gate electrodes (e.g., the cell back gate electrodes 16c, the first peripheral back gate electrodes 16n, and the second peripheral back gate electrodes 16p). The gate capping insulating layers 33 may be disposed on the upper surfaces of the gate electrodes (e.g., the cell gate electrodes 27c, the first peripheral gate electrodes 27n, and the second peripheral gate electrodes 27p). Each of the separation insulating layers 30 may be disposed between adjacent gate electrodes among the gate electrodes (e.g., the cell gate electrodes 27c, the first peripheral gate electrodes 27n, and the second peripheral gate electrodes 27p) and between adjacent insulating layers among the gate capping insulating layers 33. The insulating layers 22 may be disposed between the lower surfaces of the gate dielectric layers (e.g., the cell gate dielectric layers 24c, the first peripheral gate dielectric layers 24n, and the second peripheral gate dielectric layers 24p) and the lower source/drain patterns (e.g., the cell lower source/drain pattern 78c, the first peripheral lower source/drain pattern 78n, and the second peripheral lower source/drain pattern 79p).

Each of the insulating structures (e.g., the insulating liner 54 and the insulating pattern 56) may be disposed at the same level as a level of the upper source/drain patterns (e.g., the cell upper source/drain patterns 35c, the first peripheral upper source/drain patterns 35n, and the second peripheral upper source/drain patterns 35p) and the cell contact plugs 57c. For example, the lower surfaces of the insulating structures (e.g., the insulating liner 54 and the insulating pattern 56) may be disposed at the same level as a level of the lower surfaces of the upper source/drain patterns (e.g., the cell upper source/drain patterns 35c, the first peripheral upper source/drain patterns 35n, and the second peripheral upper source/drain patterns 35p), and the upper surfaces of the insulating structures (e.g., the insulating liner 54 and the insulating pattern 56) may be disposed at the same level as a level of the upper surfaces of the cell contact plugs 57c. The insulating structures may include an insulating pattern 56, and an insulating liner 54 covering side and lower surfaces of the insulating pattern 56, respectively. The insulating pattern 56 may include an oxide, and the insulating liner 54 may include a nitride. The pad pattern 63a may be disposed on the upper surfaces of the insulating structures (e.g., the insulating liner 54 and the insulating pattern 56).

The memory region CR may further include a bit line shield structure 88, and the memory region CR and the peripheral region PR may further include an insulating structures (e.g., an insulating liner 85 and an insulating pattern 86) and an insulating layer 90.

The insulating structures may include an insulating pattern 86 and an insulating liner 85. The insulating liner 85 may cover the upper surface of the insulating pattern 86, and may cover side surfaces of the lower source/drain patterns (e.g., the cell lower source/drain pattern 78c, the first peripheral lower source/drain pattern 78n, and the second peripheral lower source/drain pattern 79p), side surfaces of the conductive patterns (e.g., the bit line 83c, the first peripheral lower interconnection 83n, and the second peripheral lower interconnection 83p), and lower surfaces.

With reference to FIG. 6, the bit line shield structure 88 may include vertical portions 88V disposed between the bit lines 83c, and plate portions 88P in FIG. 6 extending from the vertical portions 88V and vertically overlapping with the bit lines 83c. The bit line shield structure 88 may be spaced apart from the bit lines 83c by the insulating liner 85. The insulating layer 90 may be disposed below the insulating structures (e.g., the insulating liner 85 and the insulating pattern 86) and the bit line shield structure 88.

The vertical active patterns (e.g., the cell vertical active patterns 21c, the first peripheral vertical active patterns 21n, and the second peripheral vertical active patterns 21p) may include single-crystal silicon.

The cell upper source/drain patterns 35c and the first peripheral upper source/drain patterns 35n may include a first polysilicon such as, for example, polysilicon having an N-type conductivity. The second peripheral upper source/drain patterns 35p may include a second polysilicon such as, for example, polysilicon having a P-type conductivity type.

The cell lower source/drain pattern 78c and the first peripheral lower source/drain pattern 78n may include a third polysilicon such as, for example, polysilicon of an N-type conductivity type. The second peripheral lower source/drain pattern 79p may include a fourth polysilicon such as, for example, polysilicon of a P-type conductivity type.

The cell upper source/drain SDcU may include the cell upper source/drain pattern 35c and the cell upper source/drain region 21c_U. The cell lower source/drain SDcL may include the cell lower source/drain pattern 78c and the cell lower source/drain region 21c_L. The cell upper source/drain SDcU and the cell lower source/drain SDcL may have an N-type conductivity. The cell transistor TRc may include the cell upper source/drain SDcU, the cell lower source/drain SDcL, the cell vertical channel region 21c_CH, the cell gate dielectric layer 24c, and the cell gate electrode 27c.

The first peripheral upper source/drain SDnU may include the first peripheral upper source/drain pattern 35n and the first peripheral upper source/drain region 21n_U. The first peripheral lower source/drain SDnL may include the first peripheral lower source/drain pattern 78n and the first peripheral lower source/drain region 21n_L. The first peripheral upper source/drain SDnU and the first peripheral lower source/drain SDnL may have an N-type conductivity type. The first peripheral transistor TRn may include the first peripheral upper source/drain SDnU, the first peripheral lower source/drain SDnL, the first peripheral vertical channel region 21n_CH, the first peripheral gate dielectric layer 24n, and the first peripheral gate electrode 27n. The first peripheral transistor TRn may be an N-channel metal oxide semiconductor (NMOS) transistor. The first peripheral transistors TRn may be disposed in plural, and may be disposed in NMOS transistor regions NMOS1 and NMOS2 as in FIG. 3. In FIG. 4, the first peripheral transistors TRn are illustrated as sharing the first peripheral upper source/drain pattern 35n, the first peripheral upper interconnection 57n, the first peripheral lower source/drain pattern 78n, and the first peripheral lower interconnection 83n, but embodiments of the present disclosure are not limited thereto.

The second peripheral upper source/drain SDpU may include the second peripheral upper source/drain pattern 35p and the second peripheral upper source/drain region 21p_U. The second peripheral lower source/drain SDpL may include the second peripheral lower source/drain pattern 79p and the second peripheral lower source/drain region 21p_L. The second peripheral upper source/drain SDpU and the second peripheral lower source/drain SDpL may have a P-type conductivity type. The second peripheral transistor TRp may include the second peripheral upper source/drain SDpU, the second peripheral lower source/drain SDpL, the second peripheral vertical channel region 21p_CH, the second peripheral gate dielectric layer 24p, and the second peripheral gate electrode 27p. The second peripheral transistor TRp may be an PMOS transistor. A plurality of second peripheral transistors TRp may be disposed, and may be disposed in P-channel metal oxide semiconductor (PMOS) transistor regions PMOS1 and PMOS2 as in FIG. 3. In FIG. 4, the second peripheral transistors TRp are illustrated as sharing the second peripheral upper source/drain pattern 35p, the second peripheral upper interconnection 57p, the second peripheral lower source/drain pattern 79p, and the second peripheral lower interconnection 83p, but embodiments of the present disclosure are not limited thereto.

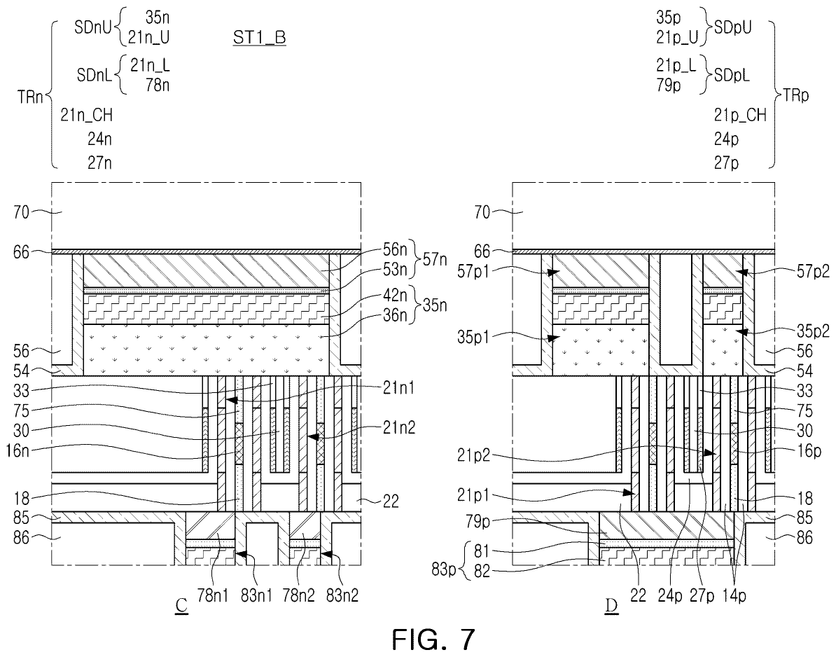

FIGS. 7 to 13 are vertical cross-sectional views of semiconductor devices according to example embodiments.

Referring to FIG. 7, the first portion ST1_A of the first structure ST1 of FIG. 4 may be replaced with the first portion ST1_B of the first structure ST1 of FIG. 7. In an example embodiment, the first peripheral vertical active patterns 21n may include first peripheral vertical active patterns 21n1 and 21n2 respectively connected to a first peripheral lower source/drain pattern 78n and a first peripheral lower interconnection 83n different from each other. For example, the first peripheral vertical active pattern 21n1 may be connected to the lower source/drain pattern 78n1 and the first peripheral lower interconnection 83n1, and the first peripheral vertical active pattern 21n2 may be connected to the lower source/drain pattern 78n2 and the first peripheral lower interconnection 83n2. The first peripheral vertical active patterns 21n1 and 21n2 may be connected to the same first peripheral upper source/drain pattern 35n and the first peripheral upper interconnection 57n.

The first peripheral vertical active pattern 21n1 and the first peripheral vertical active pattern 21n2 may respectively constitute a first peripheral transistor TRn, and the first peripheral transistor TRn constituted by the first peripheral vertical active pattern 21n1 and the first peripheral transistor TRn constituted by the first peripheral vertical active pattern 21n2 may share the first peripheral upper source/drain pattern 35n and the first peripheral upper interconnection 57n.

In an example embodiment, the second peripheral vertical active patterns 21p may include second peripheral vertical active patterns 21p1 and 21p2 connected to different second peripheral upper source/drain patterns 35p and second peripheral upper interconnections 57p, respectively. For example, the second peripheral vertical active pattern 21p1 may be connected to the second peripheral upper source/drain pattern 35p1 and the second peripheral upper interconnection 57p1, and the second peripheral vertical active pattern 21p2 may be connected to the second peripheral upper source/drain pattern 35p2 and the second peripheral upper interconnection 57p2. The second peripheral vertical active patterns 21p1 and 21p2 may be connected to the same second peripheral lower source/drain pattern 79p and the same second peripheral lower interconnection 83p.

The second peripheral vertical active pattern 21p1 and the second peripheral vertical active pattern 21p2 may respectively form a second peripheral transistor TRp, and the second peripheral transistor TRp formed by the second peripheral vertical active pattern 21p1 and the second peripheral transistor TRp formed by the second peripheral vertical active pattern 21p2 may share the same second peripheral lower source/drain pattern 79p and the same second peripheral lower interconnection 83p.

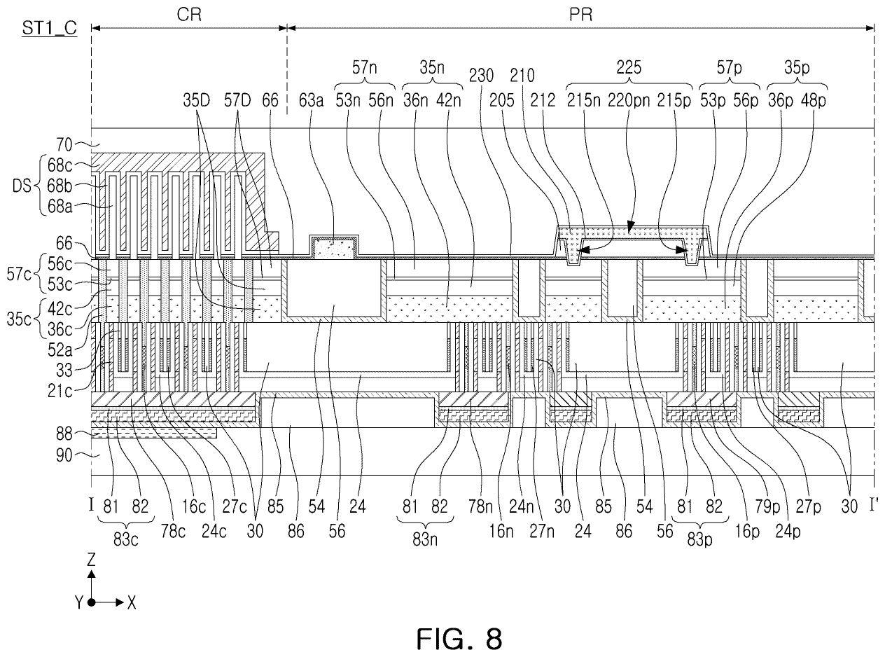

Referring to FIG. 8, the first portion ST1_A of the first structure ST1 in FIG. 4 may be replaced with the first portion ST1_C of the first structure ST1 in FIG. 8. In an example embodiment, the peripheral region PR may further include the first peripheral upper interconnections 57n, the second peripheral upper interconnections 57p, and upper interconnection structures (e.g., an interlayer insulating layer 205 and a conductive pattern 225) on the insulating liner 66. The upper interconnection structures may include an interlayer insulating layer 205 and a conductive pattern 225. The interlayer insulating layer 205 may be disposed on the insulating liner 66.

The conductive pattern 225 may include a first via 215n penetrating the interlayer insulating layer 205 and the insulating liner 66 and connected to the first peripheral upper interconnection 57n, a second via 215p penetrating the interlayer insulating layer 205 and the insulating liner 66 and connected to the second peripheral upper interconnection 57p, and an interconnection portion 220pn connected to the first via 215n and the second via 215p and disposed on the interlayer insulating layer 205.

The interconnection portion 220pn may vertically overlap with the first peripheral upper interconnection 57n and the second peripheral upper interconnection 57p. The first via 215n and the second via 215p may extend from the interconnection portion 220pn. The first via 215n and the second via 215p may be disposed between the interconnection portion 220pn, the first peripheral upper interconnection 57n, and the second peripheral upper interconnection 57p, and may electrically connect the interconnection portion 220pn, the first peripheral upper interconnection 57n, and the second peripheral upper interconnection 57p.

The conductive pattern 225pn may include a first conductive material layer 210 and a second conductive material layer 212 on the first conductive material layer 210.

The memory region CR and the peripheral region PR may further include an upper insulating liner 230 disposed on the insulating liner 66 and the upper interconnection structures (e.g., the interlayer insulating layer 205 and the conductive pattern 225). The upper insulating liner 230 may be disposed on the insulating liner 66 and may cover the side surfaces and the upper surface of the upper interconnection structures (e.g., the interlayer insulating layer 205 and the conductive pattern 225). In FIG. 8, the upper interconnection structures (e.g., the interlayer insulating layer 205 and the conductive pattern 225) may be disposed to connect the adjacent first peripheral upper interconnections 57n and the second peripheral upper interconnections 57p, but is not limited thereto. In an example embodiment, the upper interconnection structures (e.g., the interlayer insulating layer 205 and the conductive pattern 225) may connect the adjacent first peripheral upper interconnections 57n or connect the adjacent second peripheral upper interconnections 57p.

The first electrodes 68a of the data storage structure DS may penetrate the insulating liner 66 and the upper insulating liner 230, and be connected to the cell contact plug 57c.

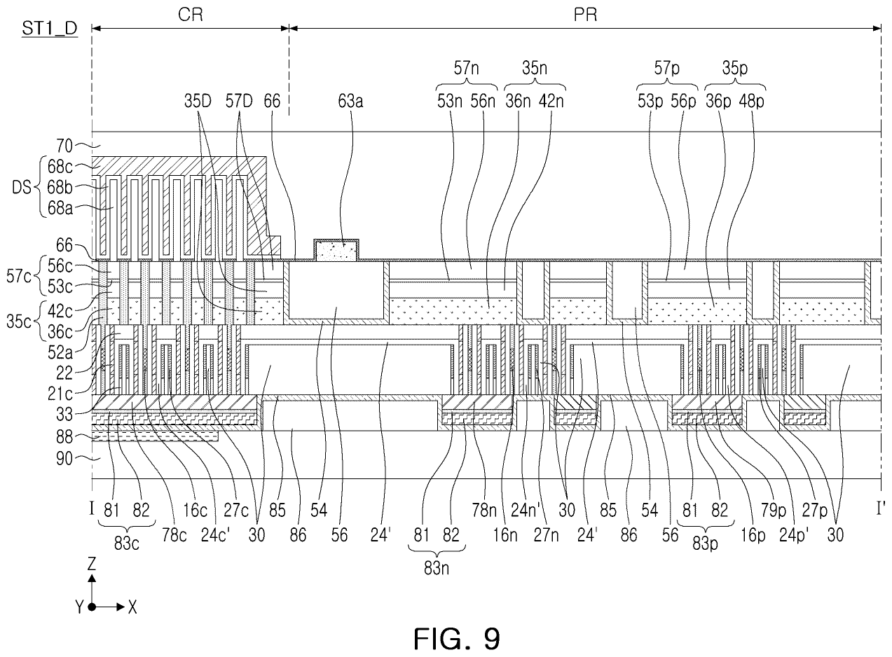

Referring to FIG. 9, the first portion ST1_A of the first structure ST1 in FIG. 4 may be replaced with the first portion ST1_D of the first structure ST1 in FIG. 9. Unlike what is shown in FIGS. 4, 5A and 5B, the cell gate dielectric layers 24c′ may be disposed between side surfaces of the cell vertical active patterns 21c and the cell gate electrodes 27c, and may extend to cover upper surfaces of the cell gate electrodes 27c. The first peripheral gate dielectric layers 24n′ may be disposed between side surfaces of the first peripheral vertical active patterns 21n and the first peripheral gate electrodes 27n, and may extend to cover upper surfaces of the first peripheral gate electrodes 27n. The second peripheral gate dielectric layers 24p′ may be disposed between the side surfaces of the second peripheral vertical active patterns 21p and the second peripheral gate electrodes 27p, and may extend to cover the upper surfaces of the second peripheral gate electrodes 27p.

The back gate capping insulating layers 18 may be disposed on the upper surfaces of the back gate electrodes (e.g., the cell back gate electrodes 16c, the first peripheral back gate electrodes 16n, and the second peripheral back gate electrodes 16p). The insulating layers 75 may be disposed below the lower surfaces of the back gate electrodes (e.g., the cell back gate electrodes 16c, the first peripheral back gate electrodes 16n, and the second peripheral back gate electrodes 16p). The gate capping insulating layers 33 may be disposed below the lower surfaces of the gate electrodes (e.g., cell gate electrodes 27c, first peripheral gate electrodes 27n, and second peripheral gate electrodes 27p). The insulating layers 22 may be disposed on the upper surfaces of the gate dielectric layers (e.g., the cell gate dielectric layers 24c, the first peripheral gate dielectric layers 24n, and the second peripheral gate dielectric layers 24p′).

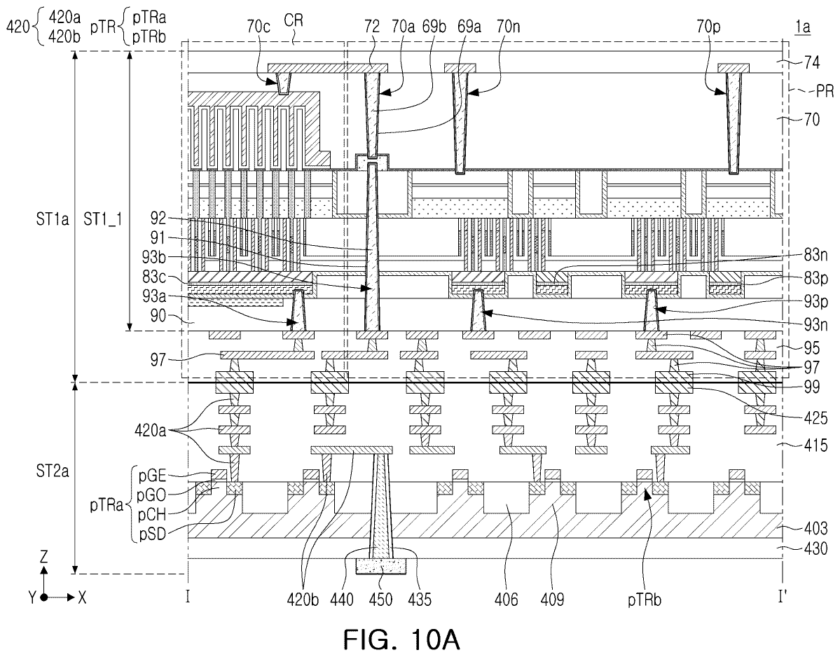

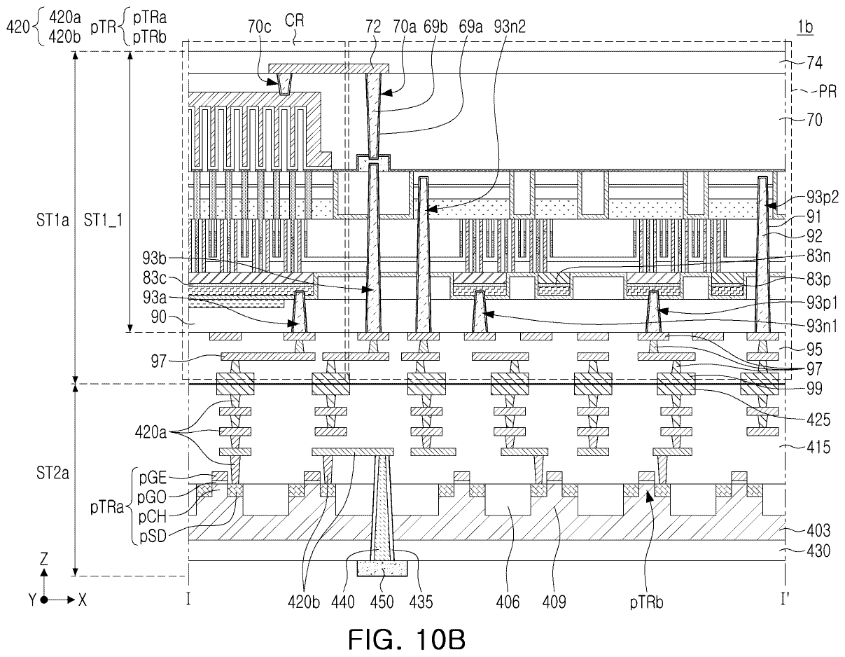

Referring to FIG. 1 and FIG. 10A, a semiconductor device 1a may include a first structure ST1a corresponding to the first structure ST1 in FIG. 1 and a second structure ST2a corresponding to the second structure ST2 in FIG. 1. The second structure ST2a may be positioned below the first structure ST1a and may be joined while in contact with the first structure ST1a.

The first structure ST1a may include a first portion ST1_1 identical to one of the first portions ST1_A, ST1_B, ST1_C, and ST1_D described with reference to FIGS. 4 to 9. For example, the first portion ST1_1 may be identical to the first portion ST1_A in FIG. 4.

The first structure ST1a may further include an insulating layer 74 on the first portion ST1_1, and an insulating layer 95 below the first portion ST1_1.

The first structure ST1a may further include upper contact plugs (e.g., connection contact plug 70a and cell contact plug 70c) and upper interconnection 72. Each of the contact plugs 70a may include a conductive plug pattern 69b and a conductive liner 69a covering a side surface and a lower surface of the conductive plug pattern 69b.

The upper contact plugs may include a cell contact plug 70c penetrating the insulating layer 70 and connected to the second electrode 68c, and a connection contact plug 70a penetrating the insulating layer 70 and the insulating liner 66 and connected to the pad pattern 63a.

The upper interconnection 72 may be connected to the contact plugs (e.g., the connection contact plug 70a and the cell contact plug 70c) on the contact plugs (e.g., the connection contact plug 70a and the cell contact plug 70c) and the insulating layer 70. The insulating layer 74 may be disposed on the insulating layer 70 and the upper interconnection 72.

The first structure ST1a may further include a first peripheral upper contact plug 70n and a second peripheral upper contact plug 70p, and upper interconnections 72 connected thereto. The first peripheral upper contact plug 70n may penetrate the insulating layer 70 and be connected to the first peripheral upper interconnection 57n. The second peripheral upper contact plug 70p may penetrate the insulating layer 70 and be connected to the second peripheral upper interconnection 57p.

The first structure ST1a may further include lower contact plugs (e.g., the contact plugs 93b, 93a, 93n, and 93p) extending upwardly through the insulating layer 90.

Each of the lower contact plugs (e.g., the contact plugs 93b, 93a, 93n, and 93p) may include a conductive plug pattern 92 and a conductive liner 91 covering a lower surface and a side surface of the conductive plug pattern 92.

The lower contact plugs may include a contact plug 93a connected to and in contact with the bit line 83c, a contact plug 93b connected to and in contact with the pad pattern 63a, a contact plug 93n connected to and in contact with the first peripheral lower interconnection 83n, and a contact plug 93p connected to and in contact with the second peripheral lower interconnection 83p.

The first structure ST1a may include the insulating layer 95 disposed below the first portion ST_1, a routing interconnection structure 97 disposed within the insulating layer 95 and electrically connected to the lower contact plugs (e.g., the contact plugs 93b, 93a, 93n, and 93p), and first bonding pads 99 connected to the routing interconnection structure 97. The lower surface of the insulating layer 95 and the lower surfaces of the first bonding pads 99 may form a coplanar surface (e.g., may be coplanar with each other).

The second structure ST2a may include a substrate 403 and an element isolation region 406 defining active regions 409 in the substrate 403. The substrate 403 may be a semiconductor substrate.

The first peripheral circuit pTRa and the second peripheral circuit pTRb may be disposed on the substrate 403.

Each of the first peripheral circuit pTRa and the second peripheral circuit pTRb may include peripheral gate structures (e.g., a peripheral gate dielectric layer pGO and a peripheral gate electrode pGE) disposed on the active region 409, peripheral source/drain regions pSD disposed within the active region 409 located on both sides of the peripheral gate structures (e.g., the peripheral gate dielectric layer pGO and the peripheral gate electrode pGE), and a peripheral channel region pCH between the peripheral source/drain regions pSD. The peripheral gate structures may include a peripheral gate dielectric layer pGO and a peripheral gate electrode pGE that are sequentially stacked.

The second structure ST2a may further include a lower routing interconnection structure 420 disposed on the substrate 403 and electrically connected to the first peripheral circuit pTRa and the second peripheral circuit pTRb, second bonding pads 425 disposed on the lower routing interconnection structure 420, and a lower insulating structure 415. The lower insulating structure 415 may be disposed on the substrate 403 and may have an upper surface that is coplanar with the upper surfaces of the second bonding pads 425. The upper surfaces of the second bonding pads 425 may be bonded to the lower surfaces of the first bonding pads 99, and the upper surface of the lower insulating structure 415 may be bonded to the lower surface of the insulating layer 95.

The lower routing interconnection structure 420 may include a first lower routing interconnection structure 420a that is electrically connected to the second bonding pads 425, and a second lower routing interconnection structure 420b that is not directly connected to the second bonding pads 425.

The second structure ST2a may further include an insulating layer 430 disposed below the substrate 403, a conductive through-via 440 penetrating the insulating layer 430 and the substrate 403 and connected to the second lower routing interconnection structure 420b, an insulating spacer 435 disposed on a side surface of the conductive through-via 440, and an input/output pad 450 connected to the conductive through-via 440 under the insulating layer 430.

In an example embodiment, the insulating layer 95, the lower contact plugs (e.g., the contact plugs 93b, 93a, 93n, and 93p), the routing interconnection structure 97, and the first bonding pads 99 may be omitted, and the second structure ST2a may be disposed on the first structure ST1a.

Referring to FIG. 10B, a semiconductor device 1b may include a first structure ST1a corresponding to the first structure ST1 in FIG. 1 and a second structure ST2a corresponding to the second structure ST2 in FIG. 1. In an example embodiment, the first peripheral upper contact plug 70n and the second peripheral upper contact plug 70p of the first structure ST1a may be omitted, and the first structure ST1a may include contact plugs 93n1, 93n2, 93p1, and 93p2. The contact plugs 93n1 and 93p1 may have the same structure as the contact plugs 93n and 93p described with reference to FIG. 10A. The contact plugs 93n2 and 93p2 may extend upward while penetrating the insulating layer 90. For example, the contact plug 93n2 may be connected to the first peripheral upper interconnection 57n by penetrating the first peripheral upper source/drain pattern 35n, and the contact plug 93p2 may be connected to the second peripheral upper interconnection 57p by penetrating the second peripheral upper source/drain pattern 35p.

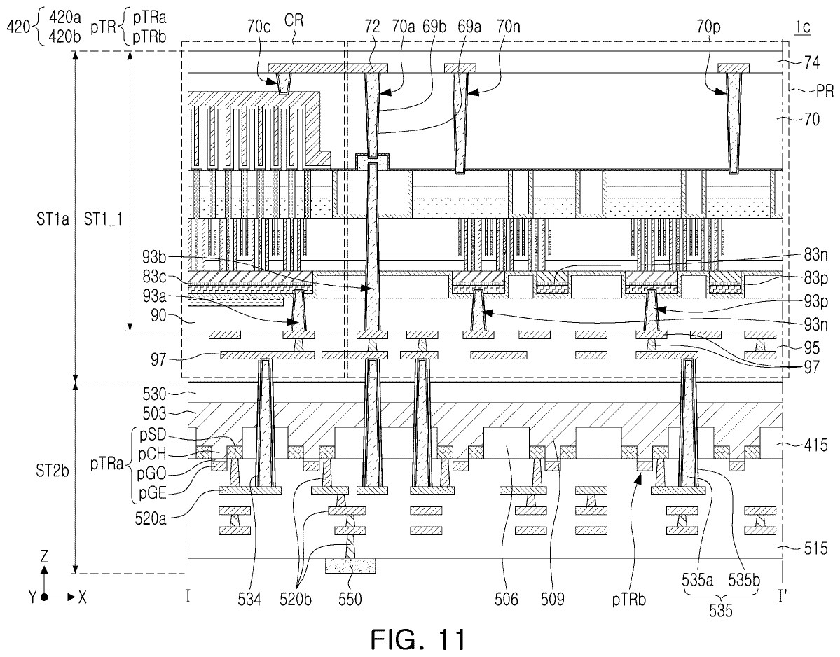

Referring to FIG. 11, a semiconductor device 1c may include a first structure ST1a and a second structure ST2b under the first structure ST1a. The first bonding pads 99 may be omitted in the first structure ST1a in FIG. 10A. The second structure ST2a in FIG. 10A may be replaced with the second structure ST2b in FIG. 11.

The second structure ST2b may include a first peripheral circuit pTRa vertically overlapping with the memory region CR, and a second peripheral circuit pTRb vertically overlapping with the peripheral region PR. The second structure ST2b may include a substrate 503 and an element isolation region 506 defining active regions 509 in the substrate 503. The substrate 503 may be a semiconductor substrate.

The first peripheral circuit pTRa and the second peripheral circuit pTRb may be disposed below the substrate 503.

Each of the first peripheral circuit pTRa and the second peripheral circuit pTRb may include peripheral gate structures (e.g., the peripheral gate dielectric layer pGO and the peripheral gate electrode pGE) disposed below the active region 509, peripheral source/drain regions pSD disposed within the active region 509, located on both sides of the peripheral gate structures (e.g., the peripheral gate dielectric layer pGO and the peripheral gate electrode pGE), and a peripheral channel region pCH between the peripheral source/drain regions pSD. The peripheral gate structures may include a peripheral gate dielectric layer pGO and a peripheral gate electrode pGE that are sequentially stacked in a downward direction.

The second structure ST2b may further include a lower routing interconnection structure 520 disposed below the substrate 503 and electrically connected to the first peripheral circuit pTRa and the second peripheral circuit pTRb, a lower insulating structure 515 covering the lower routing interconnection structure 520 under the lower routing interconnection structure 520.

The lower routing interconnection structure 520 may include a first lower routing interconnection structure 520a and a second lower routing interconnection structure 520b.

The second structure ST2b may further include an input/output pad 550 disposed below the lower insulating structure 515 and electrically connected to the second lower routing interconnection structure 520b, and an insulating layer 530 disposed between the substrate 503 and the first structure ST1a. The insulating layer 530 and the insulating layer 95 may be joined to each other.

The first structure ST1a and the second structure ST2b may further include conductive through-vias 535 that are electrically connected to the first lower routing interconnection structure 520a and extend in the vertical direction Z, penetrating the substrate 503, the insulating layer 530, and contacting and connecting with the routing interconnection structure 97, and insulating spacers 534 on the side surfaces of the conductive through-vias 535. The conductive through-vias 535 may include conductive pillars 535a and conductive liner layers 535b covering the side surfaces and upper surfaces of the conductive pillars 535a.

Therefore, a semiconductor device 1c including the first structure ST1a and the second structure ST2b may be provided.

In an example embodiment, the insulating layer 95, the lower contact plugs (e.g., the contact plugs 93b, 93a, 93n, and 93p), the routing interconnection structure 97 and the first bonding pads 99 may be omitted, and the second structure ST2b may be disposed on the first structure ST1a.

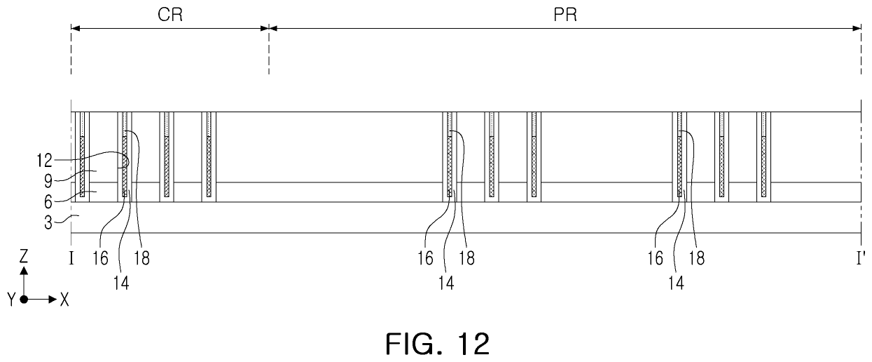

FIGS. 12 to 27 are vertical cross-sectional views illustrating a method for manufacturing a semiconductor device according to an example embodiment according to the process sequence. FIGS. 12 to 27 are cross-sectional views illustrating a region taken along the line I-I′ of FIG. 3 to illustrate an example of a method for forming a semiconductor device according to an example embodiment.

Referring to FIGS. 3 and 12, a sacrificial substrate 3, a sacrificial insulating layer 6, and a semiconductor layer 9 may be formed in sequence. The semiconductor layer 9 may be formed of a semiconductor material such as single crystal silicon.

Trenches 12 penetrating the semiconductor layer 9 and the sacrificial insulating layer 6 may be formed. The trenches 12 may be formed in the memory region CR and the peripheral region PR. Each of the trenches 12 may have a line shape extending in the second horizontal direction Y. Portions of the semiconductor layer 9 may be spaced apart from each other in the first horizontal direction X by the trenches 12.

The method may include forming a back gate dielectric layer 14 that conformally covers the inner walls of the trenches 12, forming a back gate conductive layer on the back gate dielectric layer 14, partially etching the back gate conductive layer by an etch back process to form preliminary back gate electrodes 16 that partially fill the trenches 12, and forming back gate capping insulating layers 18 that fill the remaining portions of the trenches 12 on the preliminary back gate electrodes 16. The back gate capping insulating layers 18 may be formed of an insulating material.

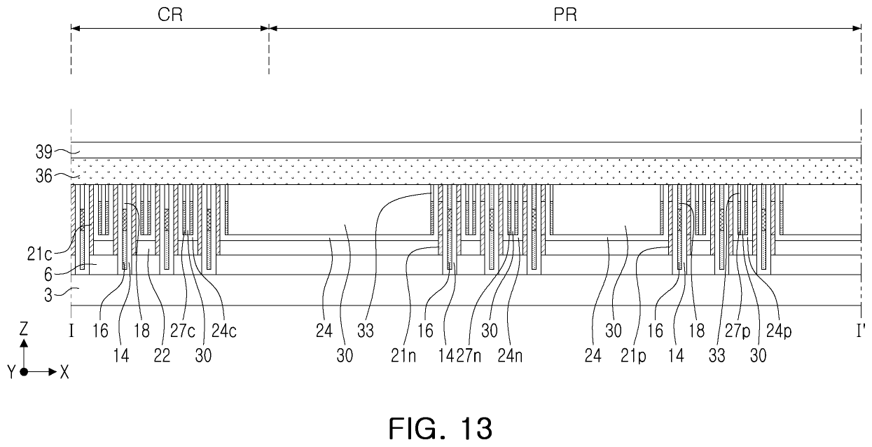

Referring to FIG. 3 and FIG. 13, the semiconductor layers 9 (see FIG. 12) may be patterned to form vertical active patterns while exposing the sacrificial insulating layer 6.

The vertical active patterns may include cell vertical active patterns 21c formed in the memory region CR, and first peripheral vertical active patterns 21n and second peripheral vertical active patterns 21p formed in the peripheral region PR.

Among the vertical active patterns (e.g., the cell vertical active patterns 21c, the first peripheral vertical active patterns 21n, and the second peripheral vertical active patterns 21p), a pair of vertical active patterns adjacent to each other may be formed on respective sides of one of the preliminary back gate electrodes 16.

An insulating layer 22 may be formed on the exposed sacrificial insulating layer 6. The upper surface of the insulating layer 22 may be disposed at a lower level than a level of the upper surfaces of the preliminary back gate electrodes 16.

Dielectric layers (e.g., the cell gate dielectric layers 24c, a dielectric layer 24, the first peripheral gate dielectric layers 24n, and the second peripheral gate dielectric layers 24p) and gate electrodes (e.g., cell gate electrodes 27c, first peripheral gate electrodes 27n, and second peripheral gate electrodes 27p) may be formed. Forming of the dielectric layers (e.g., the cell gate dielectric layers 24c, the dielectric layer 24, the first peripheral gate dielectric layers 24n, and the second peripheral gate dielectric layers 24p) and the gate electrodes (e.g., cell gate electrodes 27c, first peripheral gate electrodes 27n, and second peripheral gate electrodes 27p) may include forming dielectric layers (e.g., the cell gate dielectric layers 24c, the dielectric layer 24, the first peripheral gate dielectric layers 24n, and the second peripheral gate dielectric layers 24p) that conformally cover the upper surface of the insulating layer 22 and the exposed side surfaces of the vertical active patterns (e.g., the cell vertical active patterns 21c, the first peripheral vertical active patterns 21n, and the second peripheral vertical active patterns 21p), forming a preliminary gate conductive layer that conformally covers the dielectric layers (e.g., the cell gate dielectric layers 24c, the dielectric layer 24, the first peripheral gate dielectric layers 24n, and the second peripheral gate dielectric layers 24p), anisotropically etching the preliminary gate conductive layer to form gate conductive layers, forming separate insulating layers 30 on the gate conductive layers, and partially etching the gate conductive layers to form gate electrodes (e.g., cell gate electrodes 27c, first peripheral gate electrodes 27n, and second peripheral gate electrodes 27p), and forming gate capping insulating layers 33 on gate electrodes (e.g., the cell gate electrodes 27c, the first peripheral gate electrodes 27n, and the second peripheral gate electrodes 27p).

The dielectric layers may include cell gate dielectric layers 24c, first peripheral gate dielectric layers 24n, second peripheral gate dielectric layers 24p, and a dielectric layer 24. The cell gate dielectric layers 24c may be in contact with side surfaces of the cell vertical active patterns 21c. The first peripheral gate dielectric layers 24n may be in contact with side surfaces of the first peripheral vertical active patterns 21n. The second peripheral gate dielectric layers 24p may be in contact with side surfaces of the second peripheral vertical active patterns 21p. The dielectric layer 24 may be disposed between adjacent groups among a group of the cell vertical active patterns 21c, a group of the first peripheral vertical active patterns 21n, and a group of the second peripheral vertical active patterns 21p.

The separation insulating layers 30 may be disposed between the adjacent cell gate electrodes 27c, between the adjacent first peripheral gate electrodes 27n, between the adjacent second peripheral gate electrodes 27p, and on the dielectric layer 24.

The upper surfaces of the vertical active patterns (e.g., the cell vertical active patterns 21c, the first peripheral vertical active patterns 21n, and the second peripheral vertical active patterns 21p), the separation insulating layers 30, and the gate capping insulating layers 33 may be coplanar with each other.

Subsequently, the first semiconductor layer 36 and the protective layer 39 on the first semiconductor layer 36 may be formed. The lower surface of the first semiconductor layer 36 may be in contact with the upper surfaces of the vertical active patterns (e.g., the cell vertical active patterns 21c, the first peripheral vertical active patterns 21n, and the second peripheral vertical active patterns 21p).

The vertical active patterns (e.g., the cell vertical active patterns 21c, the first peripheral vertical active patterns 21n, and the second peripheral vertical active patterns 21p) may be formed of single crystal silicon. For example, the vertical active patterns (e.g., the cell vertical active patterns 21c, the first peripheral vertical active patterns 21n, and the second peripheral vertical active patterns 21p) may be formed of undoped single crystal silicon.

In an example, the first semiconductor layer 36 may be formed of polysilicon. For example, the first semiconductor layer 36 may be formed of undoped polysilicon.

In an example, the first semiconductor layer 36 may be formed of epitaxial silicon.

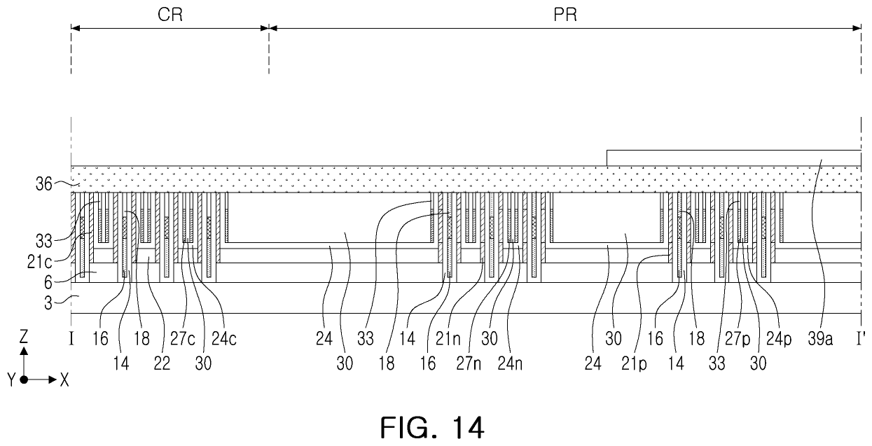

Referring to FIG. 3 and FIG. 14, the protective layer 39 (see FIG. 13) may be patterned to expose a portion of the first semiconductor layer 36 that contacts the cell vertical active patterns 21c and the first peripheral vertical active patterns 21n, and to form a lower protective pattern 39a remaining on a portion of the first semiconductor layer 36 that contacts the second peripheral vertical active patterns 21p.

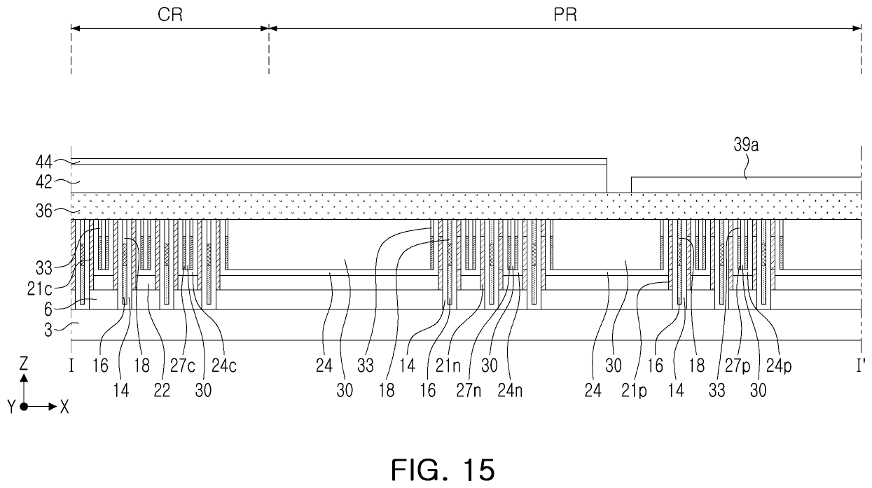

Referring to FIG. 3 and FIG. 15, a second semiconductor layer 42 and an upper protective pattern 44 may be sequentially formed on the first semiconductor layer 36 exposed by the lower protective pattern 39a. The second semiconductor layer 42 may be formed of polysilicon having an N-type conductivity.

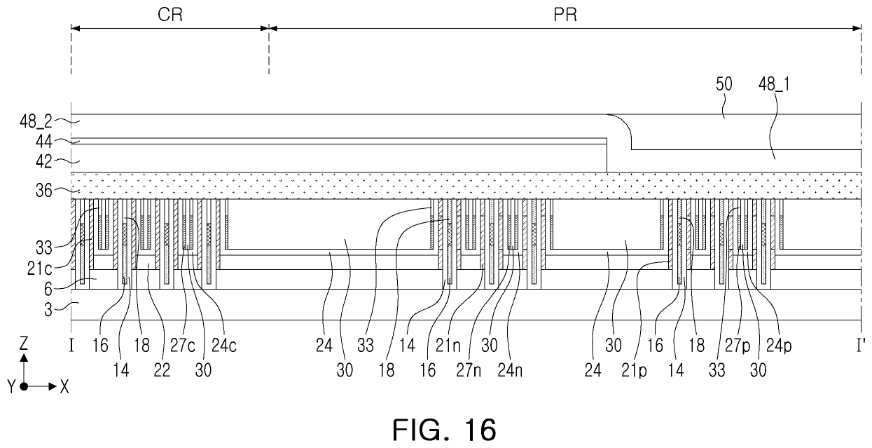

Referring to FIG. 3 and FIG. 16, the lower protective pattern 39a (see FIG. 15) may be removed. Accordingly, a portion of the first semiconductor layer 36 that contacts the second peripheral vertical active patterns 21p may be exposed.

A third semiconductor layer may be formed. The third semiconductor layer may include a first portion 48_1 in contact with the upper surface of a portion of the first semiconductor layer 36 in contact with the second peripheral vertical active patterns 21p, and a second portion 48_2 in contact with the upper surface of the upper protective pattern 44. The second portion 48_2 may be formed at a higher level than a level of the first portion 48_1. The third semiconductor layer (e.g., the first portion 48_1 and the second portion 48_2) may be formed of polysilicon having a P-type conductivity. An insulating layer may be formed on the third semiconductor layer (e.g., the first portion 48_1 and the second portion 48_2) and the insulating layer may be planarized until the upper surface of the second portion 48_2 is exposed, thereby forming a buffer insulating pattern 50 remaining on the first portion 48_1.

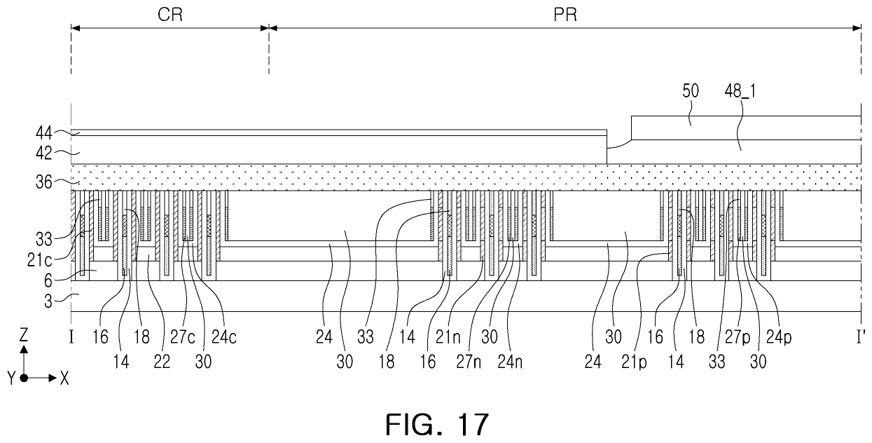

Referring to FIG. 3 and FIG. 17, the second portion 48_2 of the third semiconductor layer may be etched and removed. Therefore, the first portion 48_1 of the third semiconductor layer may remain.

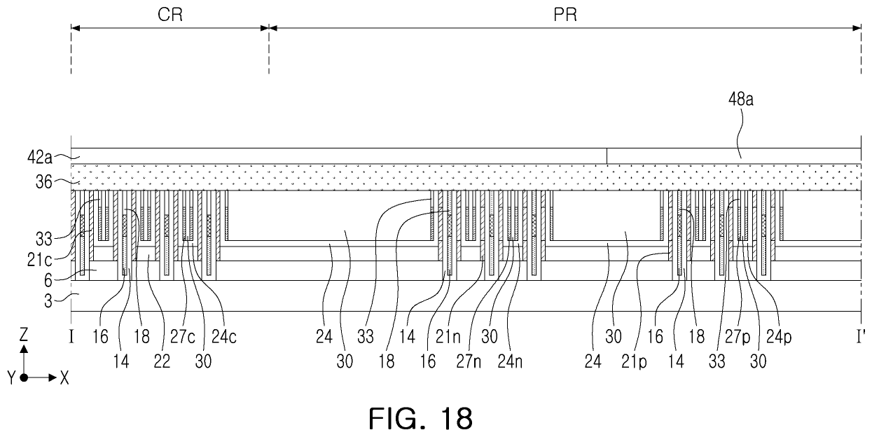

Referring to FIG. 3 and FIG. 18, a thickness of the first portion 48_1 of the third semiconductor layer and the second semiconductor layer 42 may be planarized to form a third semiconductor pattern 48a and a second semiconductor pattern 42a. During the planarization, the upper protective pattern 44 and the buffer insulating pattern 50 may be removed.

The third semiconductor pattern 48a and the second semiconductor pattern 42a may have substantially the same thickness as each other.

The first impurities in the second semiconductor pattern 42a may diffuse into the upper region of the first semiconductor layer 36, the cell vertical active pattern 21c, and the first peripheral vertical active pattern 21n. Therefore, the concentration of the first impurity in the second semiconductor pattern 42a may be higher than the concentration of the first impurity in the first semiconductor layer 36, and the concentration of the first impurity in the first semiconductor layer 36 may be higher than the concentration of the first impurity in the upper region of the cell vertical active pattern 21c and the upper region of the first peripheral vertical active pattern 21n. The first impurity may be a group V element of the periodic table such as, for example, P or As.

The second impurities in the third semiconductor pattern 48a may diffuse into the upper region of the first semiconductor layer 36 and the second peripheral vertical active pattern 21p. Therefore, the concentration of the second impurity in the third semiconductor pattern 48a may be higher than the concentration of the second impurity in the first semiconductor layer 36, and the concentration of the second impurity in the first semiconductor layer 36 may be higher than the concentration of the second impurity in the upper region of the second peripheral vertical active pattern 21p. The second impurity may be a group III element of the periodic table such as, for example, B or Al. The first semiconductor layer 36 may be formed of polysilicon doped with a group V element and a group III element.

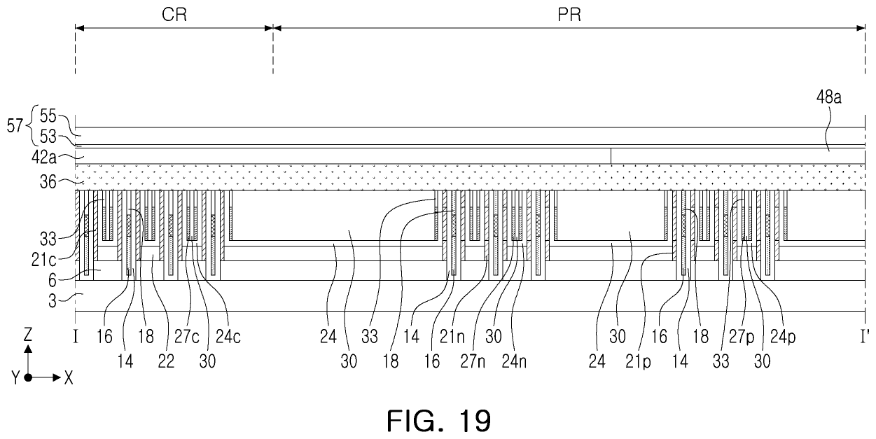

Referring to FIG. 3 and FIG. 19, a preliminary conductive layer 57 may be formed on the second semiconductor pattern 42a and the third semiconductor pattern 48a. The preliminary conductive layer 57 may include a first conductive layer 53 and a second conductive layer 55 on the first conductive layer 53. The first conductive layer 53 may include a metal-semiconductor compound, and the second conductive layer 55 may include at least one from among a metal and a metal nitride.

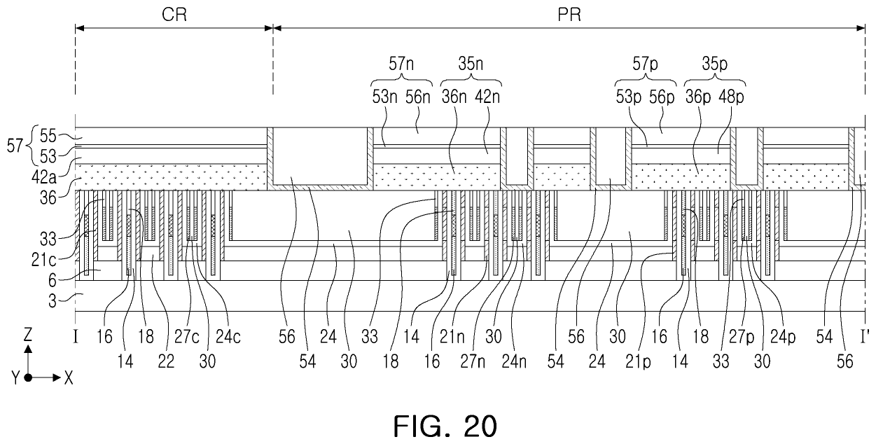

Referring to FIG. 3 and FIG. 20, insulating structures (e.g., the insulating liner 54 and the insulating pattern 56) may be formed. The insulating structures (e.g., the insulating liner 54 and the insulating pattern 56) may be formed within the peripheral region PR.

The insulating structures (e.g., the insulating liner 54 and the insulating pattern 56) may penetrate the first semiconductor layer 36, the second semiconductor pattern 42a, the third semiconductor pattern 48a, and the preliminary conductive layer 57. Each of the insulating structures may include the insulating pattern 56 and an insulating liner 54 covering the side and lower surfaces of the insulating pattern 56. The insulating pattern 56 may include an oxide, and the insulating liner 54 may include a nitride.

Within the peripheral region PR, a first semiconductor layer 36, a second semiconductor pattern 42a, a third semiconductor pattern 48a, and a preliminary conductive layer 57 may be patterned by the insulating structures (e.g., the insulating liner 54 and the insulating pattern 56). The first semiconductor layer 36 divided by the insulating structures (e.g., the insulating liner 54 and the insulating pattern 56) may be referred to as a first peripheral upper source/drain layer 36n and a third peripheral upper source/drain layer 36p. The second semiconductor pattern 42a divided by the insulating structures (e.g., the insulating liner 54 and the insulating pattern 56) may be referred to as a second peripheral upper source/drain layer 42n. The third semiconductor pattern 48a divided by the insulating structures (e.g., the insulating liner 54 and the insulating pattern 56) may be referred to as a fourth peripheral upper source/drain layer 48p. The first peripheral upper source/drain layer 36n and the second peripheral upper source/drain layer 42n may form the first peripheral upper source/drain pattern 35n. The third peripheral upper source/drain layer 36p and the fourth peripheral upper source/drain layer 48p may form the second peripheral upper source/drain pattern 35p.

The preliminary conductive layers 57 separated by the insulating structures (e.g., the insulating liner 54 and the insulating pattern 56) may be referred to as first peripheral upper interconnections 57n and second peripheral upper interconnections 57p. For example, the first conductive layer 53 and the second conductive layer 55 separated by the insulating structures (e.g., the insulating liner 54 and the insulating pattern 56) may be referred to as metal-semiconductor compound layers 53n and 53p and conductive layers 56n and 56p.

The first peripheral upper interconnections 57n and the second peripheral upper interconnections 57p may extend in the horizontal direction as illustrated in FIG. 3, and may function as interconnections that electrically connect the corresponding first peripheral vertical active patterns 21n and second peripheral vertical active patterns 21p, respectively.

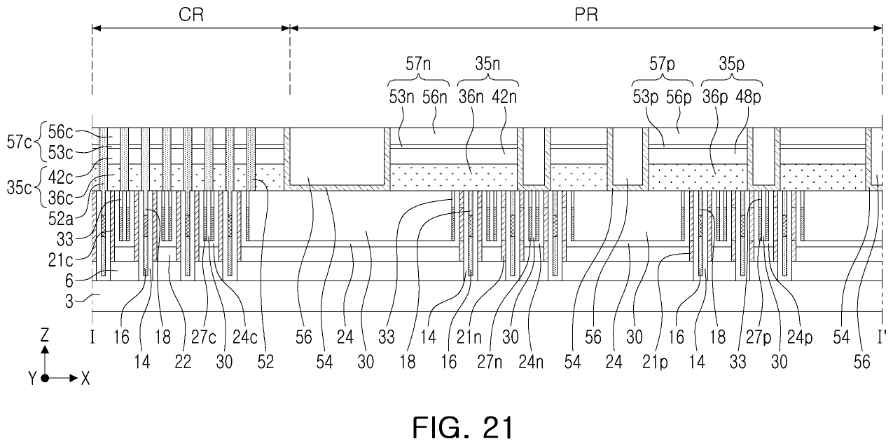

Referring to FIG. 3 and FIG. 21, cell separation patterns 52a may be formed. The cell separation patterns 52a may be formed of an insulating nitride such as, for example, silicon nitride.

The cell separation patterns 52a are illustrated as being spaced apart from the vertical active patterns 21c, but according to an example embodiment, at least one of the cell separation patterns 52a may be in contact with at least one of the vertical active patterns 21c. The cell separation pattern 52a may be formed within the memory region CR and may penetrate the first semiconductor layer 36, the second semiconductor pattern 42a and the preliminary conductive layer 57. The first semiconductor layer 36, the second semiconductor pattern 42a, and the preliminary conductive layer 57 may be patterned within the memory region CR to form the cell separation pattern 52a. The first semiconductor layer 36 and the second semiconductor pattern 42a divided by the cell separation pattern 52a may be referred to as a first cell upper source/drain pattern 36c and a second cell upper source/drain pattern 42c. The first cell upper source/drain pattern 36c and the second cell upper source/drain pattern 42c may form a cell upper source/drain pattern 35c.

The preliminary conductive layer 57 divided by the cell separation pattern 52a may be referred to as a cell contact plug 57c. For example, the first conductive layer 53 and the second conductive layer 55 of the preliminary conductive layer 57 may be divided by the cell separation pattern 52a and may be referred to as a metal-semiconductor compound layer 53c and a plug pattern 56c.

As illustrated in FIG. 20 and FIG. 21, according to an example embodiment of the present disclosure, since the peripheral upper interconnections 57n and 57p are formed by patterning the preliminary conductive layer 57, the process may be simplified compared to the case where separation patterns such as the cell separation pattern 52a are formed in the peripheral region PR and the interconnection is formed on the separation patterns. In addition, the shape and structure of the peripheral upper interconnections 57n and 57p may be implemented more diversely. For example, as illustrated in FIG. 3, since a structure such as a cell contact plug 57c is not formed on the peripheral region PR, the peripheral upper interconnections 57n and 57p may be formed with a structure larger than the cell contact plug 57c.

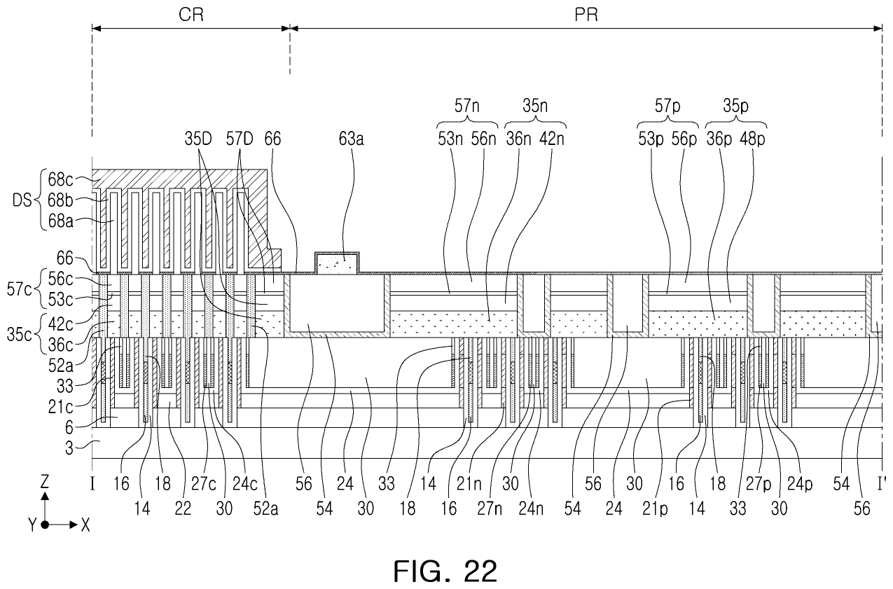

Referring to FIG. 3 and FIG. 22, a pad pattern 63a may be formed on an insulating structures (e.g., the insulating liner 54 and the insulating pattern 56) within the peripheral region PR. An insulating liner 66 covering the upper surfaces of the cell contact plugs 57c and the cell separation pattern 52a and covering the insulating structures (e.g., the insulating liner 54 and the insulating pattern 56), the pad pattern 63a, the first peripheral upper interconnections 57n and the second peripheral upper interconnections 57p in the peripheral region PR may be formed.

A data storage structure DS may be formed in the memory region CR. The data storage structure DS may include first electrodes 68a connected to the cell contact plugs 57c, penetrating the insulating liner 66, and extending in the vertical direction Z, a second electrode 68c on side surfaces and upper surfaces of the first electrodes 68a, and a dielectric layer 68b between the first electrodes 68a and the second electrode 68c.

An insulating layer 70, covering the data storage structure DS within the memory region CR and the insulating liner 66 within the peripheral region PR, may be formed. The insulating liner 66 may include a material different from the material of the insulating layer 70.

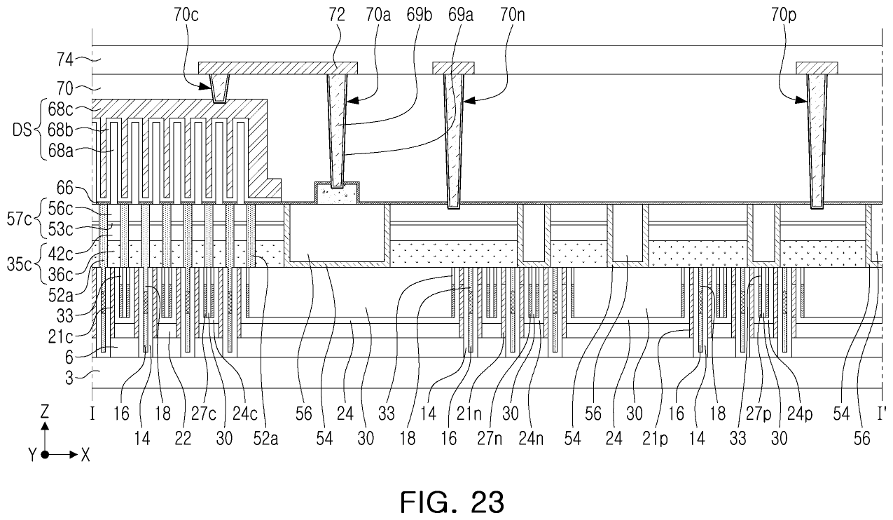

Referring to FIG. 3 and FIG. 23, contact plugs (e.g., the connection contact plug 70a and the cell contact plug 70c) and peripheral upper contact plugs (e.g., the first peripheral upper contact plug 70n and the second peripheral upper contact plug 70p) may be formed. Each of the contact plugs (e.g., the connection contact plug 70a and the cell contact plug 70c) and the peripheral upper contact plugs (e.g., the first peripheral upper contact plug 70n and the second peripheral upper contact plug 70p) may include a conductive plug pattern 69b and a conductive liner 69a covering a side surface and a lower surface of the conductive plug pattern 69b.

The contact plugs may include a cell contact plug 70c penetrating the insulating layer 70 and connected to the second electrode 68c, and a connection contact plug 70a penetrating the insulating layer 70 and the insulating liner 66 and connected to the pad pattern 63a. The peripheral upper contact plugs may include a first peripheral upper contact plug 70n penetrating the insulating layer 70 and connected to the first peripheral upper interconnections 57n, and a second peripheral upper contact plug 70p penetrating the insulating layer 70 and connected to the second peripheral upper interconnections 57p.

Upper interconnections 72 connected to the contact plugs (e.g., the connection contact plug 70a and the cell contact plug 70c) and the peripheral upper contact plugs (e.g., the first peripheral upper contact plug 70n and the second peripheral upper contact plug 70p) may be formed on the contact plugs (e.g., the connection contact plug 70a and the cell contact plug 70c), the peripheral upper contact plugs (e.g., the first peripheral upper contact plug 70n and the second peripheral upper contact plug 70p), and the insulating layer 70. An insulating layer 74 may be formed on the insulating layer 70 and the upper interconnections 72.

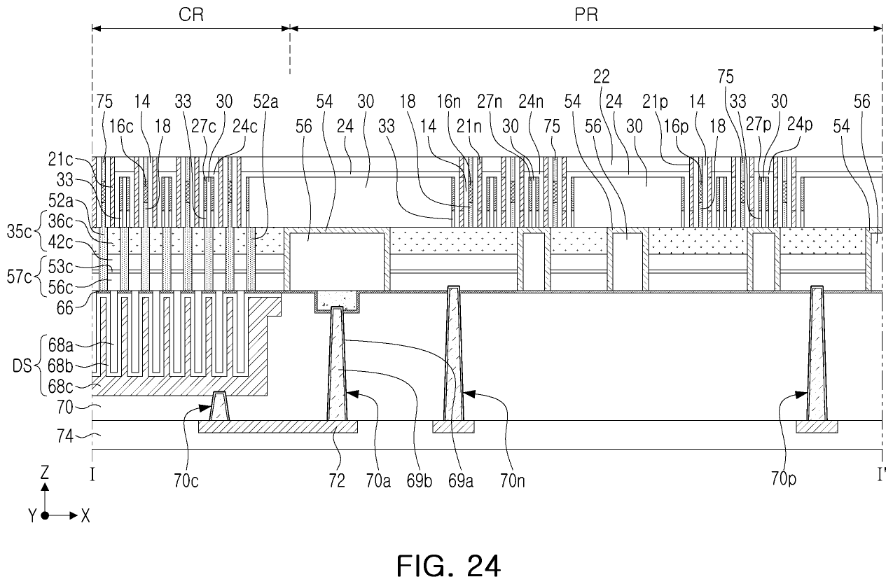

Referring to FIG. 3 and FIG. 24, after the insulating layer 74 is positioned downward, the sacrificial substrate 3 and the sacrificial insulating layer 6 may be removed. The preliminary back gate electrodes 16 may be partially etched to form back gate electrodes (e.g., the cell back gate electrodes 16c, the first peripheral back gate electrodes 16n, and the second peripheral back gate electrodes 16p), and insulating layers 75 may be formed on the back gate electrodes (e.g., the cell back gate electrodes 16c, the first peripheral back gate electrodes 16n, and the second peripheral back gate electrodes 16p). The insulating layer 22 and the vertical active patterns (e.g., the cell vertical active patterns 21c, the first peripheral vertical active patterns 21n, and the second peripheral vertical active patterns 21p) may be exposed.

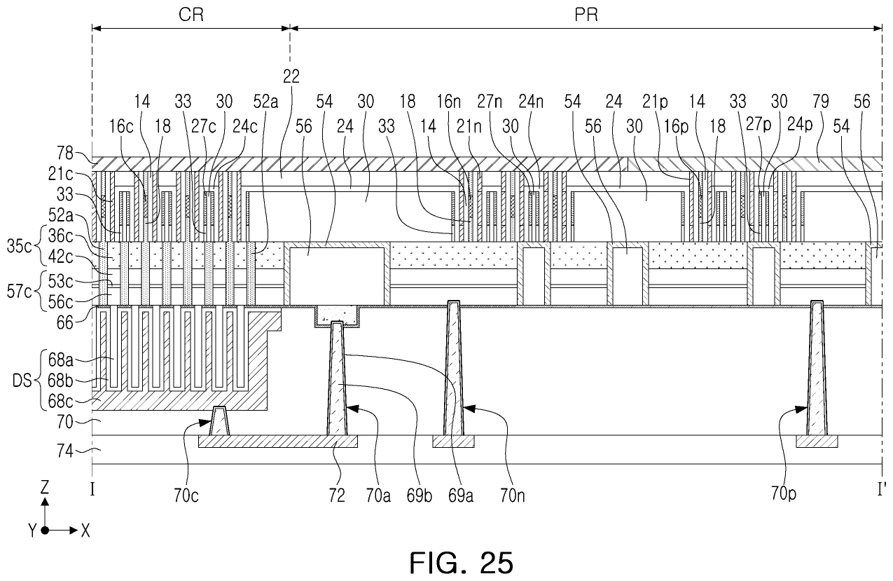

Referring to FIG. 3 and FIG. 25, a fifth semiconductor pattern 78 and a sixth semiconductor pattern 79 corresponding to the second semiconductor pattern 42a (see FIG. 18) and the third semiconductor pattern 48a (see FIG. 18) may be formed on the exposed insulating layer 22 and the vertical active patterns (e.g., the cell vertical active patterns 21c, the first peripheral vertical active patterns 21n, and the second peripheral vertical active patterns 21p), respectively. The fifth semiconductor pattern 78 and the sixth semiconductor pattern 79 may be formed in the same manner as the method of forming the second semiconductor pattern 42a (see FIG. 18) and the third semiconductor pattern 48a (see FIG. 18). Therefore, the second semiconductor pattern 42a (see FIG. 18) and the fifth semiconductor pattern 78 may be formed of the same material as each other, and the third semiconductor pattern 48a (see FIG. 18) and the sixth semiconductor pattern 79 may be formed of the same material as each other.

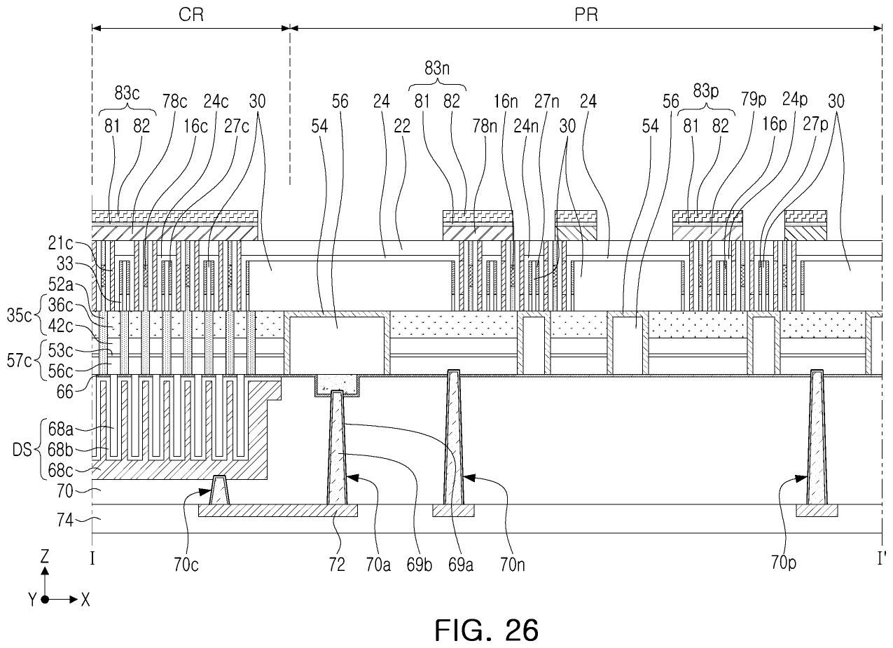

Referring to FIG. 3 and FIG. 26, conductive structures (e.g., the first conductive layer 81 and the second conductive layer 82) may be formed on the fifth semiconductor pattern 78 and the sixth semiconductor pattern 79. The conductive structures may include a first conductive layer 81 and a second conductive layer 82 that are sequentially stacked.

The conductive structures (e.g., the first conductive layer 81 and the second conductive layer 82), the fifth semiconductor pattern 78, and the sixth semiconductor pattern 79 may be patterned to form conductive patterns (e.g., the bit line 83c, the first peripheral lower interconnection 83n, and the second peripheral lower interconnection 83p) and lower source/drain patterns (e.g., the cell lower source/drain pattern 78c, the first peripheral lower source/drain pattern 78n, and the second peripheral lower source/drain pattern 79p).

The lower source/drain patterns may include a cell lower source/drain pattern 78c connected to the cell vertical active patterns 21c, a first peripheral lower source/drain pattern 78n connected to the first peripheral vertical active patterns 21n, and a second peripheral lower source/drain pattern 79p connected to the second peripheral vertical active patterns 21p.

Impurities in the cell lower source/drain pattern 78c may diffuse into the cell vertical active patterns 21c, so that source/drain regions may be formed in the cell vertical active patterns 21c. Impurities in the first peripheral lower source/drain pattern 78n may diffuse into the first peripheral vertical active patterns 21n, so that source/drain regions may be formed in the first peripheral vertical active patterns 21n. Impurities in the second peripheral lower source/drain pattern 79p may diffuse into the second peripheral vertical active patterns 21p, so that source/drain regions may be formed in the second peripheral vertical active patterns 21p.

The conductive patterns (e.g., the bit line 83c, the first peripheral lower interconnection 83n, and the second peripheral lower interconnection 83p) may include a bit line 83c that is in contact with and self-aligned to the cell lower source/drain pattern 78c, a first peripheral lower interconnection 83n that is in contact with and self-aligned to the first peripheral lower source/drain pattern 78n, and a second peripheral lower interconnection 83p that is in contact with and self-aligned to the second peripheral lower source/drain pattern 79p.

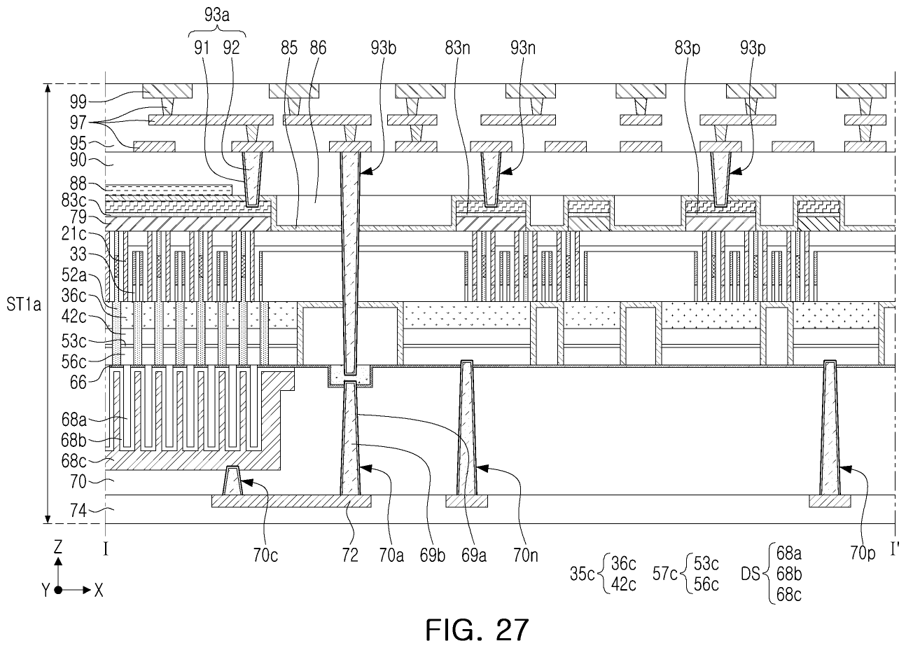

Referring to FIGS. 3 and 27, an insulating structures (e.g., the insulating liner 85 and the insulating pattern 86) and a bit line shield structure 88 may be formed. The insulating structures may include an insulating pattern 86 and an insulating liner 85 covering a lower surface of the insulating pattern 86, side surfaces of the lower source/drain patterns (e.g., the cell lower source/drain pattern 78c, the first peripheral lower source/drain pattern 78n, and the second peripheral lower source/drain pattern 79p), and side surfaces and upper surfaces of the conductive patterns (e.g., the bit line 83c, the first peripheral lower interconnection 83n, and the second peripheral lower interconnection 83p). The bit line shield structure 88 may be disposed between the bit lines 83c and may be disposed above the bit lines 83c. The bit line shield structure 88 may be spaced apart from the bit lines 83c by the insulating liner 85.

An insulating layer 90 may be formed on the insulating structures (e.g., the insulating liner 85 and the insulating pattern 86) and the bit line shield structure 88.

Contact plugs (e.g., the contact plugs 93b, 93a, 93n, and 93p) extending downward through the insulating layer 90 may be formed.

Each of the contact plugs (e.g., the contact plugs 93b, 93a, 93n, and 93p) may include a conductive plug pattern 92 and a conductive liner 91 covering the lower surface and side surface of the conductive plug pattern 92. The contact plugs may include a contact plug 93a connected to and in contact with the bit line 83c, a contact plug 93b connected to and in contact with the pad pattern 63a, a contact plug 93n connected to and in contact with the first peripheral lower interconnection 83n, and a contact plug 93p connected to and in contact with the second peripheral lower interconnection 83p.

An insulating layer 95 formed on the contact plugs (e.g., the contact plugs 93b, 93a, 93n, and 93p) and the insulating layer 90, a routing interconnection structure 97 disposed within the insulating layer 95 and electrically connected to the contact plugs (e.g., the contact plugs 93b, 93a, 93n, and 93p), and first bonding pads 99 connected to the routing interconnection structure 97 may be formed. The upper surface of the insulating layer 95 and the upper surfaces of the first bonding pads 99 may form a common surface (e.g., may be coplanar with each other). Accordingly, the first structure ST1a as in FIG. 10A may be formed.

As set forth above, according to some embodiments, peripheral upper interconnection having various sizes and structures may be implemented.

While non-limiting example embodiments have been described above with reference to the accompanying drawings, it will be apparent to those skilled in the art that modifications and variations could be made without departing from the spirit and scope of the present disclosure.

What is claimed is:

1. A semiconductor device comprising:
a memory region; and
a peripheral region,
wherein the memory region comprises:
cell vertical active patterns;
cell gate electrodes, wherein side surfaces of the cell gate electrodes face side surfaces of the cell vertical active patterns;
cell upper source/drain patterns on the cell vertical active patterns;
at least one cell contact plug on the cell upper source/drain patterns;
a cell separation pattern on a side surface of the cell upper source/drain patterns and a side surface of the at least one cell contact plug; and
a data storage structure on the at least one cell contact plug and the cell separation pattern,
wherein the peripheral region comprises:
peripheral vertical active patterns;
peripheral gate electrodes, wherein side surfaces of the peripheral gate electrodes face side surfaces of the peripheral vertical active patterns;
peripheral upper source/drain patterns on the peripheral vertical active patterns; and
at least one peripheral upper interconnection on the peripheral upper source/drain patterns,
wherein each of the cell upper source/drain patterns contacts a corresponding one of the cell vertical active patterns,
wherein the peripheral upper source/drain patterns comprise a first peripheral upper source/drain pattern, and
wherein the first peripheral upper source/drain pattern contacts a first peripheral vertical active pattern and a second peripheral vertical active pattern among the peripheral vertical active patterns.

2. The semiconductor device of claim 1, wherein the peripheral upper source/drain patterns are at a same level as a level of the cell upper source/drain patterns.

3. The semiconductor device of claim 1, wherein the at least one peripheral upper interconnection is at a same level as a level of the at least one cell contact plug.

4. The semiconductor device of claim 1, wherein the peripheral vertical active patterns are at a same level as a level of the cell vertical active patterns.

5. The semiconductor device of claim 1, wherein the at least one peripheral upper interconnection comprises a first peripheral upper interconnection on the first peripheral upper source/drain pattern, and
wherein a sides surface of the first peripheral upper interconnection is coplanar with a side surface of the first peripheral upper source/drain pattern.

6. The semiconductor device of claim 5, wherein a horizontal width of the first peripheral upper interconnection is the same as a horizontal width of the first peripheral upper source/drain pattern.

7. The semiconductor device of claim 1, wherein the memory region further comprises:
a cell lower source/drain pattern below the cell vertical active patterns; and
a bit line below the cell lower source/drain pattern, and
wherein the peripheral region further comprises:
at least one peripheral lower source/drain pattern below the peripheral vertical active patterns; and
at least one peripheral lower interconnection below the at least one peripheral lower source/drain pattern.

8. The semiconductor device of claim 7, wherein the at least one peripheral lower source/drain pattern comprises a first peripheral lower source/drain pattern contacting the first peripheral vertical active pattern and the second peripheral vertical active pattern.

9. The semiconductor device of claim 7, wherein a side surface of the at least one peripheral lower interconnection is coplanar with a side surface of the at least one peripheral lower source/drain pattern.

10. The semiconductor device of claim 7, wherein the at least one peripheral lower source/drain pattern comprises a first peripheral lower source/drain pattern and a second peripheral lower source/drain pattern spaced apart in a horizontal direction,
wherein the first peripheral lower source/drain pattern contacts the first peripheral vertical active pattern, and
wherein the second peripheral lower source/drain pattern contacts the second peripheral vertical active pattern.

11. The semiconductor device of claim 7, wherein the peripheral upper source/drain patterns further comprise:
a second peripheral upper source/drain pattern contacting a third peripheral vertical active pattern among the peripheral vertical active patterns; and
a third peripheral upper source/drain pattern contacting a fourth peripheral vertical active pattern among the peripheral vertical active patterns, and
one peripheral lower source/drain pattern among the at least one peripheral lower source/drain pattern contacts the third peripheral vertical active pattern and the fourth peripheral vertical active pattern.

12. The semiconductor device of claim 7, wherein a vertical distance from the peripheral vertical active patterns to the at least one peripheral upper interconnection is greater than a vertical distance from the peripheral vertical active patterns to the at least one peripheral lower interconnection.

13. The semiconductor device of claim 7, wherein the at least one peripheral lower interconnection is at a same level as a level of the bit line.

14. The semiconductor device of claim 1, wherein the peripheral region further comprises an upper connecting structure on the at least one peripheral upper interconnection and connecting the at least one peripheral upper interconnection.

15. A semiconductor device comprising:
a memory region; and
a peripheral region,
wherein the memory region comprises:
cell vertical active patterns;
cell gate electrodes, wherein side surfaces of the cell gate electrodes face side surfaces of the cell vertical active patterns;
cell upper source/drain patterns on the cell vertical active patterns;
at least one cell contact plug on the cell upper source/drain patterns;
a cell separation pattern on a side surface of the cell upper source/drain patterns and a side surface of the at least one cell contact plug; and
a data storage structure on the at least one cell contact plug and the cell separation pattern,
wherein the peripheral region comprises:
peripheral vertical active patterns;
peripheral gate electrodes, wherein side surfaces of the peripheral gate electrodes face side surfaces of the peripheral vertical active patterns;
peripheral upper source/drain patterns on the peripheral vertical active patterns;
at least one peripheral upper interconnection on the peripheral upper source/drain patterns,
wherein the cell upper source/drain patterns respectively contact a corresponding one of the cell vertical active patterns, and
wherein a horizontal width of each of the peripheral upper source/drain patterns is greater than a horizontal width of each of the cell upper source/drain patterns.

16. The semiconductor device of claim 15, wherein a horizontal width of each of the at least one peripheral upper interconnection is greater than a horizontal width of a respective one of the at least one cell contact plug.

17. The semiconductor device of claim 15, wherein at least one peripheral upper source/drain pattern among the peripheral upper source/drain patterns vertically overlaps with a plurality of cell vertical active patterns among the cell vertical active patterns.

18. The semiconductor device of claim 15, wherein the cell vertical active patterns and the peripheral vertical active patterns comprise single crystal silicon, and
wherein the cell upper source/drain patterns and the peripheral upper source/drain patterns comprise polysilicon.

19. The semiconductor device of claim 15, wherein the at least one cell contact plug comprises a same material as a material of the at least one peripheral upper interconnection.

20. A semiconductor device comprising:
a memory region; and
a peripheral region,
wherein the memory region comprises:
cell vertical active patterns;
cell gate electrodes, wherein side surfaces of the cell gate electrodes face side surfaces of the cell vertical active patterns;
contact structures on the cell vertical active patterns;
a cell separation pattern on side surfaces of the contact structures;
a data storage structure on the contact structures and the cell separation pattern;
an insulating layer on the data storage structure and extending onto the peripheral region; and
an upper contact plug penetrating through the insulating layer and connected to the data storage structure,
wherein the peripheral region comprises:
peripheral vertical active patterns;
peripheral gate electrodes, wherein side surfaces of the peripheral gate electrodes face side surfaces of the peripheral vertical active patterns;
peripheral interconnection structures on the peripheral vertical active patterns; and
peripheral upper contact plugs penetrating the insulating layer and connected to the peripheral interconnection structures, and
wherein the peripheral interconnection structures respectively contact a plurality of peripheral vertical active patterns among the peripheral vertical active patterns, and the peripheral interconnection structures are lower than a lower surface of the data storage structure.
